(19) United States
(12) Patent Application Publication
(10) Pub. No.: US 2025/0309770 A1
(43) Pub. Date: Oct. 2, 2025

(54) BIDIRECTIONAL CURRENT SENSOR, CHARGER INTEGRATED CIRCUIT, AND ELECTRONIC DEVICE

(71) Applicant: Samsung Electronics Co., Ltd., Suwon-si (KR)

(72) Inventors: Jinwoo SO, Suwon-si (KR); Hyebong KO, Suwon-si (KR)

(73) Assignee: Samsung Electronics Co., Ltd., Suwon-si (KR)

(21) Appl. No.: 18/918,430

(22) Filed: Oct. 17, 2024

(30) Foreign Application Priority Data
Mar. 28, 2024 (KR) 10-2024-0042720

(51) Int. Cl. H02M 3/158; H02J 7/00; H02M 1/00

(52) U.S. Cl. CPC H02M 3/1582; H02J 7/0068; H02M 1/0009; H02M 1/0095; H02J 2207/20

(57) ABSTRACT

A bidirectional current sensor, a charger integrated circuit, and an electronic device are provided. The charger integrated circuit includes a bidirectional switching converter including a first switching element to a fourth switching element, a first bidirectional current sensor connected to an end and another end of the first switching element and configured to output a first detection signal and a second detection signal indicating results of detecting an over-current and a zero-current with respect to a first switching current of the first switching element that is turned on, and a second bidirectional current sensor connected to an end and another end of the fourth switching element and configured to output a third detection signal and a fourth detection signal indicating results of detecting an over-current and zero-current with respect to a second switching current of the fourth switching element that is turned on.

### CROSS-REFERENCE TO RELATED APPLICATION

This application is based on and claims priority under 35 U.S.C. § 119 to Korean Patent Application No. 10-2024-0042720, filed on Mar. 28, 2024, in the Korean Intellectual Property Office, the disclosure of which is incorporated by reference herein in its entirety.

### BACKGROUND

The inventive concepts relate to charging and power supply, and more particularly, to bidirectional current sensors, charger integrated circuits, and electronic devices.

According to rapid development of electronic devices, electronic devices, by which information or data may be exchanged, have been widely used. For electronic devices, chargeable batteries are used as power supply units to provide the benefit of mobility. As capacities of batteries are limited, it is required that batteries are charged at proper times. Travel adapter (TA) converts power, which is provided from a domestic power source (e.g., alternating current (AC) 110 to 220 V) or other power supply units (e.g., a computer), into direct current (DC) power for charging batteries, provides the DC power to electronic devices, and the electronic devices may use the DC power for charging the batteries.

Recently, research has been conducted on a technology in which a mobile device such as a smartphone simultaneously supports wired charging and wireless charging and charging periods for wired charging and wireless charging are reduced according to needs of users. Accordingly, converters included in electronic devices, which used to be two-level converters, have been implemented as three-level converters. A three-level converter constructs an input voltage higher than an input voltage of a two-level converter, and includes more devices (e.g., four devices) than devices included in the two-level converter. Charger circuits support various types of switching modes to stably support wireless charging operations and wired charging operations even when an input power is unstable during wired charging and wireless charging. When switching modes are transited, seamless mode transition in charging circuits is required to prevent or reduce generation of an over-current or a zero-current in the charger circuits.

When a charger circuit includes a three-level converter, a plurality of current sensors configured to detect an over-current and a plurality of current sensors configured to detect a zero-current are required according to switching modes in the charger circuit. Accordingly, due to the plurality of current sensors according to the switching modes, sizes of chips of the charger circuit including three-level converter are likely to increase.

### SUMMARY

The inventive concepts provide bidirectional current sensors connected to a switching element, charger integrated circuits including two bidirectional current sensors, and electronic devices including the charger integrated circuit, to allow seamless mode transition, protect the device, and reduce sizes of chips.

According to some aspects of the inventive concepts, there is provided a charger integrated circuit including a bidirectional switching converter comprising a first switching element, a second switching element, a third switching element, and a fourth switching element, the first to fourth switching elements connected in series to a first input/output node, an inductor connected between an end of the third switching element and a second input/output node, and a capacitor connected between an end of the second switching element and another end of the third switching element, a first bidirectional current sensor connected to an end and another end of the first switching element, the first bidirectional current sensor configured to generate a first sensing voltage and a second sensing voltage corresponding to a first switching current flowing through the first switching element that is turned on, based on resistances set in response to turning on of the first switching element, bias currents generated internally, and a resistance of the first switching element that is turned on, and output a first detection signal and a second detection signal indicating a result of detecting an over-current with respect to the first switching current and a result of detecting a zero-current with respect to the first switching current, based on a first reference voltage and a second reference voltage which vary according to switching modes, and the first sensing voltage and the second sensing voltage, and a second bidirectional current sensor connected to an end and another end of the fourth switching element, the first bidirectional current sensor configured to generate a third sensing voltage and a fourth sensing voltage corresponding to a second switching current flowing through the fourth switching element that is turned on, based on resistances set in response turning on of the fourth switching element and bias currents generated internally and a resistance of the fourth switching element that is turned on, and output a third detection signal and a fourth detection signal indicating a result of detecting of an over-current with respect to the second switching current and a result of detecting of a zero-current with respect to the second switching current, based on the first reference voltage, the second reference voltage, the third sensing voltage, and the fourth sensing voltage.

According to some aspects of the inventive concepts, there is provided a bidirectional current sensor including a sensing circuit connected to a first node and a second node, the first and second nodes connected to a switching element included in a bidirectional switching converter, the sensing circuit configured to output a plurality of bias currents and a plurality of offset currents based on a switching voltage provided to the switching element, an amplification circuit configured to output a plurality of amplification voltages based on the plurality of bias currents, a sensing voltage generation circuit configured to output a plurality of sensing voltages corresponding to a switching current flowing through the switching element, based on the plurality of offset currents and the plurality of amplification voltages, and a detection circuit configured to output an over-current detection signal indicating whether an over-current for the switching current has been detected and a zero-current detection signal indicating whether a zero-current for the switching current has been detected, based on a plurality of reference voltages varying according to switching modes and the plurality of sensing voltages.

According to some aspects of the inventive concepts, there is provided an electronic device including a battery, a charger integrated circuit configured to charge the battery in a buck mode, provide power to an external device based on a voltage charged in the battery in a boost mode, and perform, in a buck-boost mode, at least one of a first operation to charge the battery and a second operation to provide the power to the external device. The charger integrated circuit includes a bidirectional switching converter comprising a plurality of switching elements connected in series to a first input/output node, a bidirectional current sensor configured to sense a first sensing voltage and a second sensing voltage corresponding to a switching current flowing through a switching element that is turned on, in response to turning on of the switching element of the plurality of switching elements, and configured to output a first detection signal and a second detection signal indicating a result of detecting an over-current with respect to the switching current and a result of detecting a zero-current with respect to the switching current, based on a first reference voltage and a second reference voltage which vary according to switching modes, and the first sensing voltage and the second sensing voltage, and a gate driver configured to generate a plurality of switching voltages respectively provided to the plurality of switching elements, based on the first detection signal and the second detection signal.

### BRIEF DESCRIPTION OF THE DRAWINGS

Embodiments will be more clearly understood from the following detailed description taken in conjunction with the accompanying drawings in which:

FIG. 1 is a block diagram of an electronic device according to some example embodiments;

FIG. 2 is a circuit diagram of a bidirectional switching converter and a battery according to some example embodiments;

FIGS. 3A and 3B illustrate a power path formed in a buck mode, according to some example embodiments;

FIGS. 4A and 4B each illustrate a power path formed in a boost mode, according to some example embodiments;

FIGS. 5A and 5B are timing charts of a bidirectional switching converter in a buck mode, according to some example embodiments;

FIG. 6 is a block diagram of a controller according to some example embodiments;

FIG. 7 is a circuit diagram of a first bidirectional current sensor according to some example embodiments;

FIG. 8 is a graph illustrating a relationship between a sensing voltage and a switching current of the first bidirectional current sensor shown in FIG. 7;

FIG. 9 is a circuit diagram of an adjustment circuit included in the first bidirectional current sensor shown in FIG. 7;

FIG. 10 is a circuit diagram of a second bidirectional current sensor according to some example embodiments;

FIG. 11 is a graph illustrating a relationship between the inductor current and the reference currents changing according to switching mode transition.

FIGS. 12 to 17 illustrate timing charts of the reference voltages, the sensing voltages, the inductor current, and the detection signals in the switching modes and switching mode transition.

FIG. 18 is a block diagram of an electronic system according to some example embodiments.

### DETAILED DESCRIPTION

Hereinafter, some example embodiments will be described in detail with reference to the accompanying drawings.

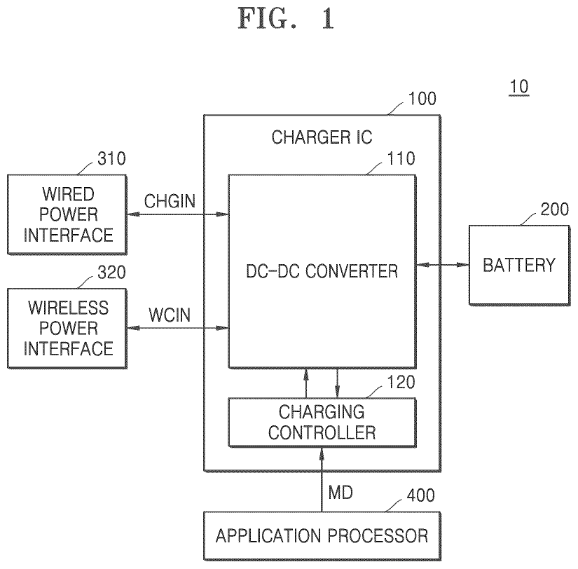

FIG. 1 is a block diagram of an electronic device 10 according to some example embodiments.

Referring to FIG. 1, the electronic device 10 may include a mobile device or a portable device, e.g., a smart phone, a tablet, or a personal computer (PC), or may include an electronic vehicle. However, example embodiments are not limited to the example described above.

The electronic device 10 may include a charger integrated circuit (IC) 100, a battery 200, a wired power interface 310, a wireless power interface 320, and an application processor 400. In addition, the electronic device 10 may further include peripheral devices.

In some example embodiments, the battery 200 may be embedded in the electronic device 10. In some example embodiments, the battery 200 may be attached to/detached from the electronic device 10. The battery 200 may include one or more battery cells. A plurality of battery cells may be connected in series or in parallel. When an external charger is not connected to the electronic device 10, the battery 200 may supply power to the electronic device 10.

The charger IC 100 may be configured to charge the battery 200. The charger IC 100 may be configured to supply power to an external device connected to the charger IC 100, based on a voltage charged in the battery 200. Here, the electronic device may be connected to the electronic device 10, for example, through the wired power interface 310 and/or the wireless power interface 320.

The charger IC 100 may be configured to support various functions, e.g., a zero-current sensing (ZCS) function, an under-voltage lockout (UVLO) function, an over-current limit (OCL) function (or an over-current protection (OCP) function), an over-voltage protection (OVP) function, a soft-start function to reduce an inrush current, a foldback current limit function, a hiccup mode function to protect short circuits, an over-temperature protection (OTP) function, and the like.

The charger IC 100 may include a bidirectional switching converter 110 and a controller 120. In some example embodiments, the bidirectional switching converter 110 may be implemented as a three-level converter (or referred to as a three-level DC/DC converter). Here, three-level indicates the number of voltage levels used for switching operations. The three-level converter may be configured to generate an output voltage by switching an input voltage, a (½)*input voltage, and a ground voltage (for example, 0 V).

The bidirectional switching converter 110 may be configured to perform a converting operation in any one of the plurality of switching modes. In some example embodiments, the plurality of switching modes may include a buck mode, a boost mode, and a buck-boost mode.

In the buck mode, the bidirectional switching converter 110 may be configured to perform a buck converting operation to buck the input voltage and generate an output voltage corresponding to the voltage that has been bucked, and charge the battery 200 based on the output voltage. In the buck converting operation, power may be provided to the battery 200 from at least one external device connected to the electronic device 10 through the wired power interface 310 and/or the wireless power interface 320.

In the boost mode, the bidirectional switching converter 110 may be configured to perform a boost converting operation to boost the input voltage and generate an output voltage corresponding to the voltage that is boosted, and provide power to the external device based on the output voltage. In the boost converting operation, power may be provided from the battery 200 to at least one external device.

In the buck-boost mode, the bidirectional switching converter 110 may be configured to perform at least one of a first operation to charge the battery 200 and a second operation to provide power to the external device. In some example embodiments, in the buck-boost mode, the bidirectional switching converter 110 may be configured to perform a buck converting operation or a boosting operation according to an amount of power provided from the external device or an amount of power provided to the external device.

The controller 120 may be configured to control mode transition of the plurality of switching modes of the bidirectional switching converter 110. The controller 120 may be configured to control switching operations of the bidirectional switching converter 110 according to switching modes. The controller 120 may be configured to control switching operations of the bidirectional switching converter 110 such that an output voltage of the bidirectional switching converter 110 may maintain a target level (e.g., a first target level set for the output voltage). The controller 120 may be configured to control the switching operations of the bidirectional switching converter 110 such that a voltage between two ends of a flying capacitor (hereinafter, referred to as a flying capacitor voltage) provided in the bidirectional switching converter 110 may maintain a target level (e.g., a second target level set for the flying capacitor voltage).

The controller 120 may be configured to generate control signals for controlling the switching operations in the switching modes of the bidirectional switching converter 110.

The wired power interface 310 for wired charging may include a wired charger circuit. The wireless power interface 320 for wireless charging may include a wireless charger circuit. For example, the wired charger circuit and the wireless charger circuit may include a rectifier, a regulator, and the like.

In the buck mode, the charger IC 100 may be configured to charge the battery 200 based on a first input voltage CHGIN and/or a second input voltage WCIN. The first input voltage CHGIN may be provided by the wired power interface 310, and the second input voltage WCIN may be provided by the wireless power interface 320.

In the boost mode, the charger IC 100 may be configured to provide power to the wired power interface 310 and/or the wireless power interface 320, based on the voltage charged in the battery 200.

In the buck-boost mode, the charger IC 100 may be configured to charge the battery 200 or provide power to the wireless power interface 320, based on the first input voltage CHGIN provided from the wired power interface 310. Alternatively, the charger IC 100 may be configured to charge the battery 200 or provide power to the wired power interface 310, based on the second input voltage WCIN provided from the wireless power interface 320. Battery charging and providing power to the interfaces may be simultaneously performed.

The charger IC 100 may be configured to provide power to the wireless power interface 320 based on the first input voltage CHGIN and the voltage of the battery 200, or may be configured to provide power to the wired power interface 310 based on the second input voltage WCIN and the voltage of the battery 200.

For example, a travel adapter (TA) or an auxiliary battery may be electrically connected to the wired power interface 310. The TA may be configured to convert power, which is provided from a domestic power source (e.g., alternating current (AC) 110 to 220 V) or other power supply units (e.g., a computer), into direct current (DC) power for charging batteries, provide the DC power to the electronic device 10. In the buck mode or the buck-boost mode, the charger IC 100 may be configured to charge the battery 200 or provide power to the wireless power interface 320 by using the first input voltage CHGIN received from the TA or the auxiliary battery.

For example, an on the go (OTG) device (e.g., an OTG USB device) may be connected to the wired power interface 310. The charger IC 100 may be configured to provide power to the OTG device through the wired power interface 310. In the boost mode, the charger IC 100 may be configured to provide power to the OTG device based on the voltage charged in the battery 200. Alternatively, in the buck mode, the charger IC 100 may be configured to charge the battery 200 and simultaneously provide power to the OTG device, based on the second input voltage WCIN received from the wireless power interface 320.

For example, a wireless power circuit may be connected to the wireless power interface 320. The wireless power circuit may include a wireless power transmitting circuit and/or a wireless power receiving circuit. In the buck mode or the buck-boost mode, the charger IC 100 may be configured to charge the battery 200 by using the second input voltage WCIN received from the wireless power circuit or provide power to the wireless power circuit through the wireless power interface 320. The charger IC 100 may be configured to provide power to the wireless power circuit based on the battery 200 in the boost mode, or may be configured, in the buck mode, to charge the battery 200 based on the first input voltage CHGIN received from the wired power interface 310 and simultaneously provide power to the wireless power circuit.

The application processor 400 may be configured to recognize a device connected to the wired power interface 310 and the wireless power interface 320. Alternatively, the application processor 400 may be configured to recognize voltages provided from the wired power interface 310 and the wireless power interface 320 (e.g., the first input voltage CHGIN and the second input voltage WCIN).

The application processor 400 may be configured to generate mode signals MD for determining switching modes, according to the interfaces or input voltages connected to the application processor 400, and provide the mode signals to the controller 120. For example, when the first input voltage CHGIN is applied through the wired power interface 310 and the wireless power circuit is connected to the wireless power interface 320, the application processor 400 may recognize the first input voltage CHGIN and the wireless power circuit and generate a mode signal MD indicating the buck-boost mode. When the OTG device is connected to the wired power interface 310 or the wireless power transmission circuit is connected to the wireless power interface 320, the application processor 400 may generate a mode signal MD indicating a boost mode. Like this, the application processor 400 may be configured to generate the mode signals MD indicating a plurality of switching modes and provide the mode signals MD to the controller 120. The controller 120 may be configured to control the bidirectional switching converter 110 such that switching operations corresponding to the mode signals MD are performed.

The application processor 400 may be configured to provide a plurality of digital signals DSs, respectively having logical values corresponding determined switching modes, to the controller 120. Each of the plurality of digital signals DSs may instruct the controller 120 to change voltage levels of reference voltages used for performing various functions (e.g., a ZCS function, an UVLO function, and the like) of the charger IC 100. In some example embodiments, the plurality of digital signals DSs may include a first digital signal and a second digital signal. The first digital signal and the second digital signal may change voltage levels of a first reference voltage and a second reference voltage used for performing the ZCS function and an OCL function. The controller 120 may be configured to selectively change the voltage levels of the reference voltages, based on the logical levels of the plurality of digital signals DSs.

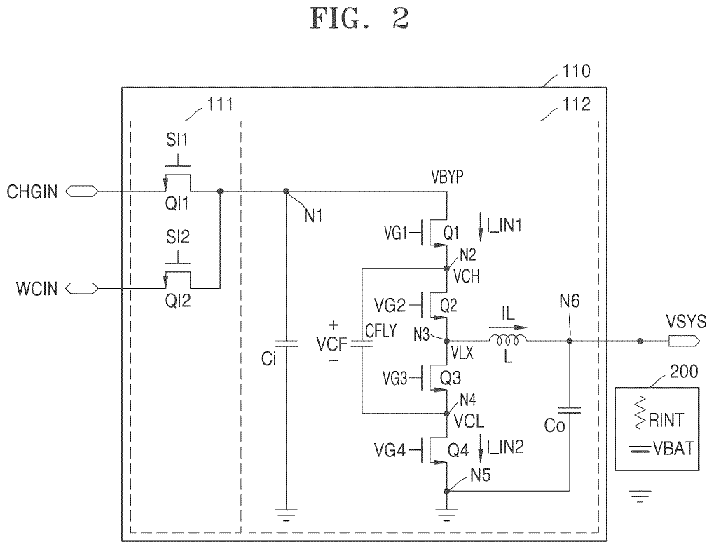

FIG. 2 is a circuit diagram of the bidirectional switching converter 110 and the battery 200 according to some example embodiments.

Referring to FIG. 2, the bidirectional switching converter 110 may include an input/output selection circuit 111 and a switching circuit 112.

The input/output selection circuit 111 may include a first input transistor QI1 and a second input transistor QI2. The first input transistor QI1 and the second input transistor QI2 may be connected in parallel to a first node N1. The first node N1 may be referred to as ‘first input/output node’. An input transistor may be referred to as ‘input element’.

The first input voltage CHGIN may be applied or the OTG device may be connected to the first input transistor QI1. The second input voltage WCIN may be applied or the wireless power circuit may be connected to the second input transistor QI2. The first input transistor QI1 may be turned on or turned off based on a first input control signal SI1. For example, when the first input voltage CHGIN is applied to the first input transistor QI1 or the OTG device is connected to the electronic device 10 through the wired power interface 310, the first input control signal SI1 may have an active level (or a turn-on level), and the first input transistor QI1 may be turned on in response to the active level of the first input control signal SI1. The second input transistor QI2 may be turned on or turned off based on a second input control signal SI2. For example, when the second input voltage WCIN is applied to a second input/output terminal 102 or the wireless transmission circuit is connected to the electronic device 10 through the wireless power interface 320, the second input control signal SI2 may have an active level, and the second input transistor QI2 may be turned on in response to the active level of the second input control signal SI2. The first input control signal SI1 and the second input control signal SI2 may be received from the controller 120.

The switching circuit 112 may include a plurality of switching elements, an inductor L, a first capacitor Ci, a second capacitor Co, a third capacitor CFLY, and a current sensor.

In some example embodiments, when the bidirectional switching converter 110 is implemented as a three-level converter, the plurality of switching elements may include first to fourth switching elements. In some example embodiments, the first to fourth switching elements may correspond to a first switching transistor Q1, a second switching transistor Q2, a third switching transistor Q3, and a fourth switching transistor Q4.

The first capacitor Ci may be configured to stabilize an input voltage applied to the first node N1, in the buck mode or the buck-boost mode. For example, the first capacitor Ci may be configured to rectify an output voltage of a square wave, which is output to the first node N1, into a direct voltage, in the boost mode or the buck-boost mode.

The first switching transistor Q1, the second switching transistor Q2, the third switching transistor Q3, and the fourth switching transistor Q4 may be connected in series to the first node N1. An end (e.g., a first electrode) of the first switching transistor Q1 may be connected to the first node N1, another end (e.g., a second electrode) of the first switching transistor Q1 may be connected to a second node N2, and a first switching voltage VG1 may be input to a gate electrode of the first switching transistor Q1. An end of the second switching transistor Q2 may be connected to the second node N2, another end of the second switching transistor Q2 may be connected to a third node N3, and a second switching voltage VG2 may be input to a gate electrode of the second switching transistor Q2. An end of the third switching transistor Q3 may be connected to the third node N3, another end of the third switching transistor Q3 may be connected to a fourth node N4, and a third switching voltage VG3 may be input to a gate electrode of the third switching transistor Q3. An end of the fourth switching transistor Q4 may be connected to the fourth node N4, another end of the fourth switching transistor Q4 may be connected to a fifth node N5, and a fourth switching voltage VG4 may be input to a gate electrode of the fourth switching transistor Q4. A ground voltage may be applied to the fifth node N5.

The first switching transistor Q1 may be turned on or turned off based on the first switching voltage VG1. The second switching transistor Q2 may be turned on or turned off based on the second switching voltage VG2. The third switching transistor Q3 may be turned on or turned off based on the third switching voltage VG3. The fourth switching transistor Q4 may be turned on or turned off based on the fourth switching voltage VG4.

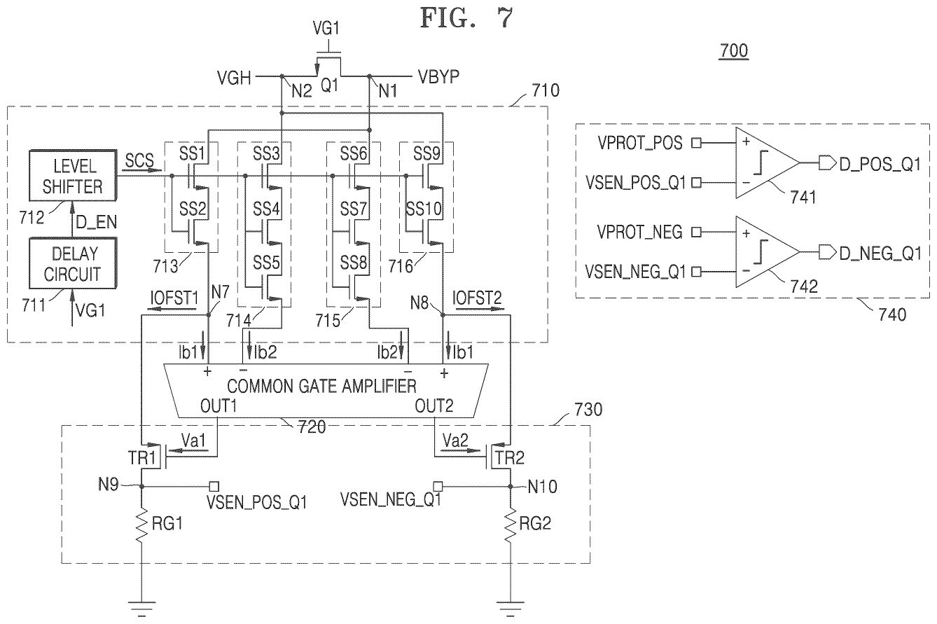

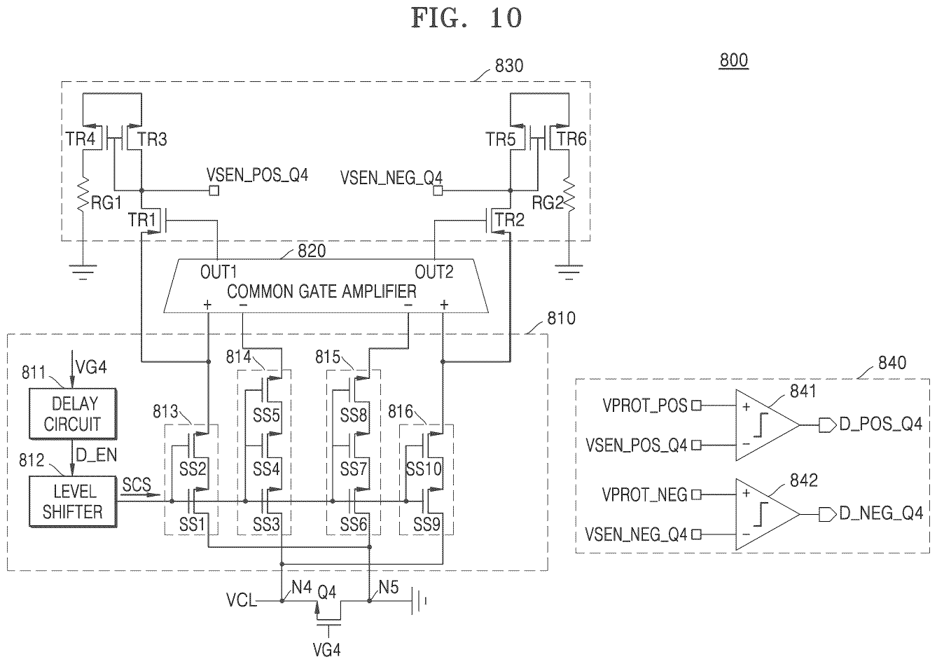

A current sensor may be connected to each of the first switching transistor Q1 and the fourth switching transistor Q4. For example, a bidirectional current sensor may be connected to the two ends of the first switching transistor Q1, and a bidirectional current sensor may be connected to the two ends of the fourth switching transistor Q4. When the first switching transistor Q1 is turned on, a first switching current I_IN1 may flow through the first switching transistor Q1 that has been turned on. The bidirectional current sensor may be configured to sense the first switching current I_IN1. When the fourth switching transistor Q4 is turned on, a second switching current I_IN2 may flow through the fourth switching transistor Q4 that has been turned on. The bidirectional current sensor may be configured to sense the second switching current I_IN2. The two bidirectional current sensors respectively connected to the first switching transistor Q1 and the fourth switching transistor Q4 may be included in the controller 120. The bidirectional current sensors will be described later with reference to FIGS. 7 and 10. Sensing the first switching current I_IN1 and the second switching current I_IN2 may be equal to sensing an inductor current IL.

The first switching voltage VG1, the second switching voltage VG2, the third switching voltage VG3, and the fourth switching voltage VG4 may include periodic signals each having frequency, and the frequency may vary according to a buck rate in a buck-converting operation and a boost rate in a boost-converting operation. The first switching voltage VG1, the second switching voltage VG2, the third switching voltage VG3, and the fourth switching voltage VG4 may be provided by the controller 120.

The first switching voltage VG1 and the fourth switching voltage VG4 may be complementary signals, and the second switching voltage VG2 and the third switching voltage VG3 may be complementary signals. Accordingly, the first switching transistor Q1 and the fourth switching transistor Q4 may be configured to perform a complementary switching operation, and the second switching transistor Q2 and the third switching transistor Q3 may be configured to perform a complementary switching operation.

The third capacitor CFLY may be connected to the second node N2 and the fourth node N4. An end of the third capacitor CFLY may be connected to the second node N2, and another end of the third capacitor CFLY may be connected to the fourth node N4. The third capacitor CFLY may be referred to as a flying capacitor.

The inductor L may be connected to the third node N3 and a sixth node N6. The sixth node N6 may be referred to as a second input/output node. The second capacitor Co may be connected to the sixth node N6. A LC filter (e.g., a low pass filter (LPF) may be formed by the inductor L and the second capacitor Co, and the inductor L and the second capacitor Co may be configured to remove high-frequency components found at an output terminal, only allow direct components to pass, and deliver the direct components to the output terminal.

The inductor L may be configured to store energy generated due to the inductor current IL flowing through the inductor L and discharge the energy that has been stored. The inductor current IL may flow from the third node N3 to the sixth node N6 according to the buck converting operation of the bidirectional switching converter 110, or may flow from the sixth node N6 to the third node N3 according to the boost converting operation of the bidirectional switching converter 110. When the inductor current IL flows from the third node N3 to the sixth node N6, it may be assumed that a value of the inductor current IL is positive, and when the inductor current IL flows from the sixth node N6 to the third node N3, it may be assumed that the value of the inductor current IL is negative. A circuit path is formed by electrical connection between elements of the switching circuit 112 in the buck mode, the boost mode, and the buck-boost mode, and therefore, the inductor current IL may correspond to the first switching current I_IN1 and the second switching current I_IN2.

The bidirectional switching converter 110 may be configured to operate as a buck converter in the buck mode or in some sections of the buck-boost mode and generate a first output voltage by bucking a first voltage VBYP. The first voltage VBYP may include the first input voltage CHGIN and/or the second input voltage WCIN. The first output voltage may be output as a system voltage VSYS through the second input/output node (e.g., the sixth node N6). In addition, the first output voltage may be provided to the battery 200, and the battery 200 may be charged. The battery 200 may include an internal resistor RINT, and a battery voltage VBAT of the battery 200 after charging may be equal to the first output voltage.

The bidirectional switching converter 110 may be configured to operate as a boost converter in the boost mode or in other sections of the buck-boost mode and generate a second output voltage by boosting the battery voltage VBAT. The second output voltage may be output through the first input/output node (e.g., the first node N1), and the bidirectional switching converter 110 may be configured to provide power to the wired power interface 310 and/or the wireless power interface 320, based on the second output voltage.

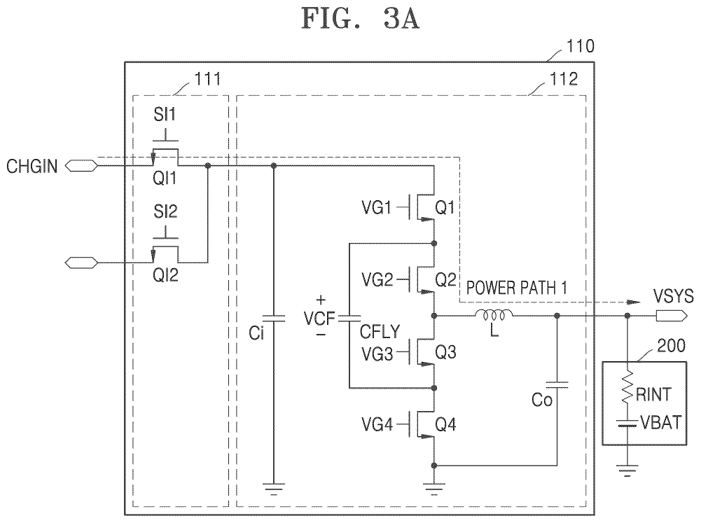

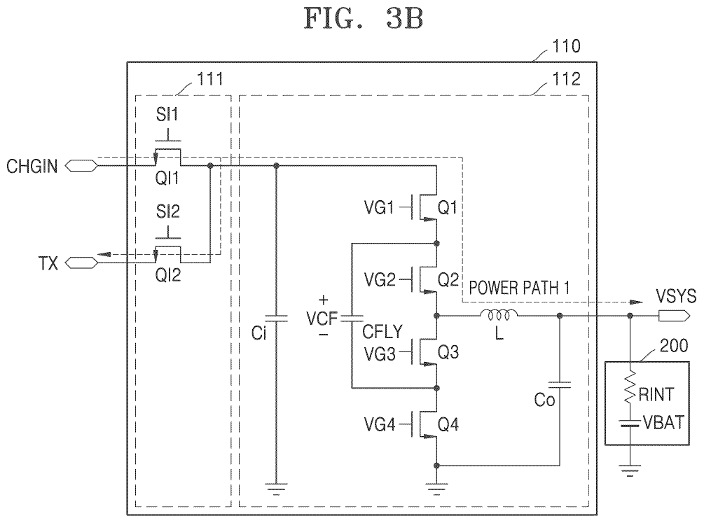

FIGS. 3A and 3B illustrate a power path formed in the buck mode, according to some example embodiments. In FIG. 3A, it is assumed that the first input voltage CHGIN is applied to the input/output selection circuit 111, and in FIG. 3B, it is assumed that the first input voltage CHGIN is applied to and the wireless power transmission circuit TX is connected to the input/output selection circuit 111.

Referring to FIG. 3A, a first input power may apply the first input voltage CHGIN to the input/output selection circuit 111, and the first input transistor QI1 may be turned on in response to the first input control signal SI1 having the active level. The second input transistor QI2 may be turned off in response to the second input control signal SI2 having an inactive level. The bidirectional switching converter 110 may be configured to perform a buck converting operation as a buck converter. The bidirectional switching converter 110 may be configured to perform a switching operation based on the first input voltage CHGIN, and thus, a first power path POWER PATH 1 may be formed. A current provided from the first input power may be provided to the battery 200 and/or an internal system of the electronic device 10 through the inductor L. The bidirectional switching converter 110 may be configured to charge the battery 200 and provide the power into the internal system of the electronic device 10 by performing the buck converting operation.

Referring to FIG. 3B, the first input power and the wireless power transmission circuit TX may be connected to the input/output selection circuit 111. The first input transistor QI1 may be turned on in response to the first input control signal SI1 having the active level. The second input transistor QI2 may be turned on in response to the second input control signal SI2 having the active level. The first input power may provide power to the wireless power transmission circuit TX through the first input transistor QI1 and the second input transistor QI2. Accordingly, in addition to the first power path POWER PATH 1, a power path may be formed from the wired power interface 310 to the wireless power interface 320 in the input/output selection circuit 111.

Although FIGS. 3A and 3B illustrate some examples of the first power path POWER PATH 1 formed when the bidirectional switching converter 110 performs the buck converting operation based on the first input voltage CHGIN, however, embodiments are not limited to FIGS. 3A and 3B. According to some example embodiments, the bidirectional switching converter 110 may be configured to perform the buck converting operation based on the second input voltage WCIN provided from the wireless power interface 320, a power path similar to the first power path POWER PATH 1 may be formed when the bidirectional switching converter 110 performs the buck converting operation based on the second input voltage WCIN, and the power path may be formed from the wireless power interface 320 to the wired power interface 310 in the input/output selection circuit 111.

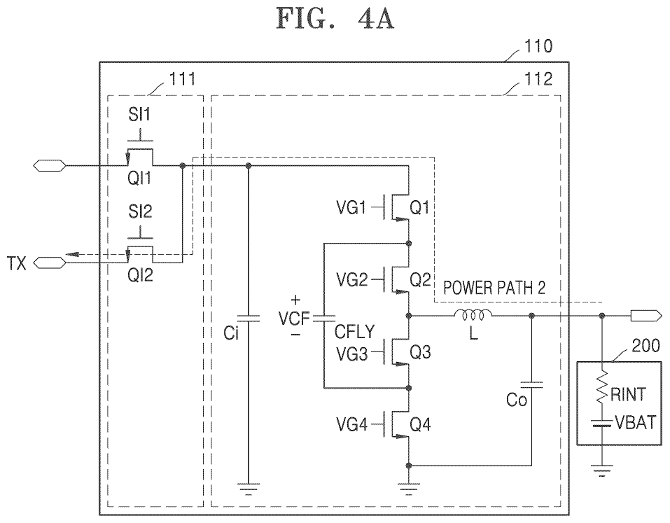

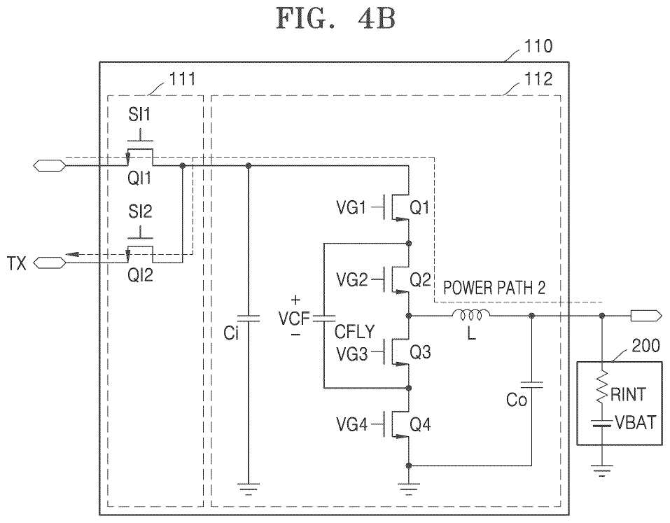

FIGS. 4A and 4B illustrate a power path formed in the boost mode, according to some example embodiments. In FIG. 4A, it is assumed that the wireless power transmission circuit TX is connected to the input/output selection circuit 111, and in FIG. 4B, it is assumed that the first input voltage CHGIN is applied and the wireless power transmission circuit TX is connected to the input/output selection circuit 111.

Referring to FIG. 4A, the wireless power transmission circuit TX may be connected to the input/output selection circuit 111. The second input transistor QI2 may be turned on in response to the second input control signal SI2 having the active level. The first input transistor QI1 may be turned off in response to the first input control signal SI1 having the inactive level. The bidirectional switching converter 110 may be configured to perform a boost converting operation as a boost converter. The bidirectional switching converter 110 may be configured to perform a switching operation based on the battery voltage VBAT, and thus, a second power path POWER PATH 2 may be formed. A current provided from the battery 200 may be provided to the wireless power transmission circuit TX through the inductor L. In some example embodiments, the OTG device may be connected to the input/output selection circuit 111, and the current provided from the battery 200 may also be provided to the OTG device.

Referring to FIG. 4B, the wireless power transmission circuit TX may be connected and the first input voltage CHGIN may be applied to the input/output selection circuit 111. The first input transistor QI1 and the second input transistor QI2 may be turned on in response to the first input control signal SI1 and the second input control signal SI2 having the active levels. A current provided from the wired power interface 310 may be provided to the wireless power transmission circuit TX. Accordingly, in addition to the second power path POWER PATH 2 formed as a result of the boost converting operation of the bidirectional switching converter 110, a power path may be formed from the wired power interface 310 to the wireless power interface 320 in the input/output selection circuit 111. In some example embodiments, the OTG device may be connected to the input/output selection circuit 111, and the second input voltage WCIN may be applied to the input/output selection circuit 111 through the wireless power interface 320. The current provided from the battery 200 and a current provided from a second power based on the second input voltage WCIN may be provided to the OTG device.

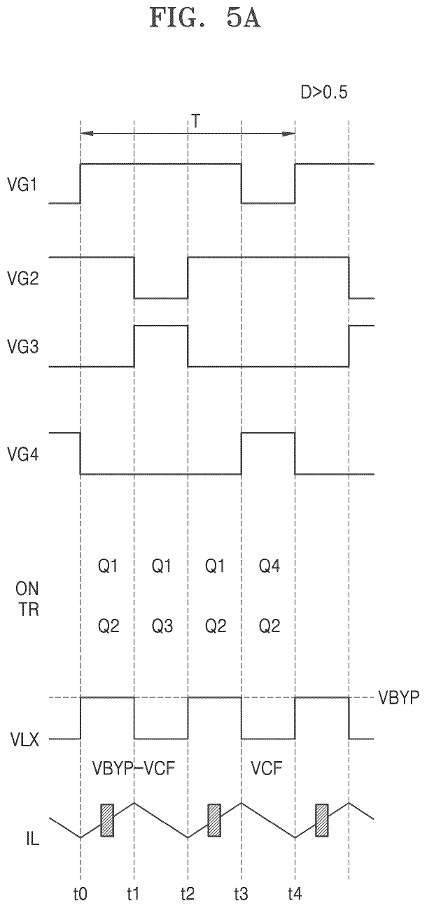

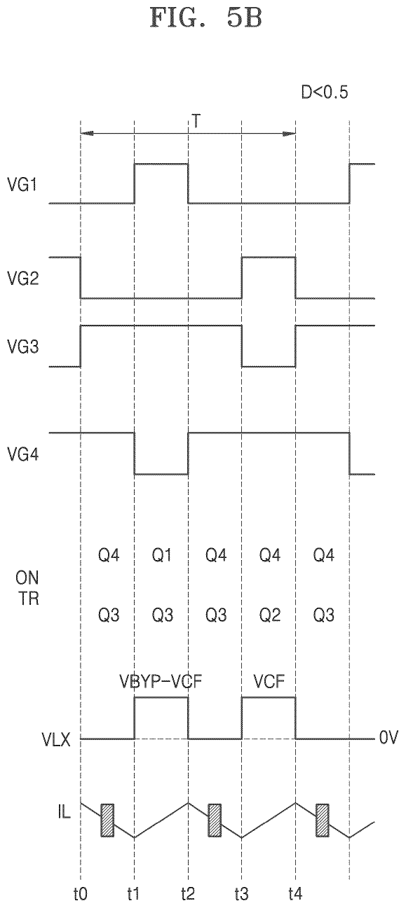

FIGS. 5A and 5B are timing charts of the bidirectional switching converter 110 under the buck mode according to some example embodiments. In FIG. 5A, a duty ratio D is greater than 0.5, and in FIG. 5B, the duty ratio D is less than 0.5.

Referring to FIGS. 5A and 5B, the bidirectional switching converter 110 may be configured to perform a buck converting operation based on the first switching voltage VG1, the second switching voltage VG2, the third switching voltage VG3, and the fourth switching voltage VG4. For example, when the first switching voltage VG1 has the active level (e.g., a logic high level), the first switching transistor Q1 may be turned on, and when the first switching voltage VG1 has the inactive level (e.g., the logic low level), the first switching transistor Q1 may be turned off. The first switching voltage VG1, the second switching voltage VG2, the third switching voltage VG3, and the fourth switching voltage VG4 may include signals having a same frequency, an interval in which the first switching voltage VG1, the second switching voltage VG2, the third switching voltage VG3, and the fourth switching voltage VG4 have the active level in a period may be variable, and an interval in which the first switching voltage VG1, the second switching voltage VG2, the third switching voltage VG3, and the fourth switching voltage VG4 have the inactive level in the period may also be variable. The first switching voltage VG1 and the fourth switching voltage VG4 may be complementary signals, and the second switching voltage VG2 and the third switching voltage VG3 may be complementary signals.

At a time point t0, the first switching transistor Q1 may be turned on. The second switching transistor Q2 may be turned on. The first node N1, the second node N2, and the third node N3 may be electrically connected to one another. A third level VLX may have a voltage level identical or substantially identical to a voltage level of the first voltage VBYP, and the inductor current IL increases.

At a time point t1, the second switching transistor Q2 may be turned off and the third switching transistor Q3 may be turned on. The first node N1, the second node N2, the third node N3, and the fourth node N4 may be electrically connected to one another, a voltage level of the voltage VCL is equal to the voltage level of the third voltage VLX, and a current flows to the inductor L through the first switching transistor Q1, the third capacitor CFLY, and the third switching transistor Q3. The third voltage VLX may have a voltage level reduced by a flying capacitor voltage VCF of the third capacitor CFLY from the first voltage VBYP. For example, when the flying capacitor voltage VCF is ½ times the first voltage VBYP (e.g., ½*VBYP), the third voltage VLX may have a voltage level identical or substantially identical to a voltage level of the flying capacitor voltage VCF (e.g., ½*VBYP). As the voltage level of the third voltage VLX decreases, the inductor current IL decreases.

At a time point t2, the third switching transistor Q3 may be turned off and the second switching transistor Q2 may be turned on. The third voltage VLX may have the voltage level identical or substantially identical to the voltage level of the first voltage VBYP, and the inductor current IL increases.

At a time point t3, the first switching transistor Q1 may be turned off and the fourth switching transistor Q4 may be turned on. The second node N2, the third node N3, the fourth node N4, and the fifth node N5 may be electrically connected to one another, and the current flows to the inductor L through the fourth switching transistor Q4, the third capacitor CFLY, and the second switching transistor Q2. The third voltage VLX may have a voltage level (e.g., ½*VBYP) identical or substantially identical to the voltage level of the flying capacitor voltage VCF, and as the voltage level of the third voltage VLX decreases, the inductor current IL decreases.

Referring to FIG. 5B, at the time point to, the fourth switching transistor Q4 and the third switching transistor Q3 may be turned on. The third node N3, the fourth node N4, and the fifth node N5 may be electrically connected to one another, the third voltage VLX may have a voltage level identical or substantially identical to a voltage level of the ground voltage, and the inductor current IL decreases.

At the time point t1, the fourth switching transistor Q4 may be turned off and the first switching transistor Q1 may be turned on. The first node N1 and the second node N2 may be electrically connected to each other, and the third node N3 and the fourth node N4 may be electrically connected to each other. The third voltage VLX may have the voltage level reduced from the first voltage VBYP by the flying capacitor voltage VCF of the third capacitor CFLY, and as the voltage level of the third voltage VLX increases, the inductor current IL increases.

At the time point t2, the fourth switching transistor Q4 may be turned on and the first switching transistor Q1 may be turned off. The third voltage VLX may have the voltage level identical or substantially identical to the voltage level of the ground voltage, and the inductor current IL decreases.

At a time point t3, the second switching transistor Q2 may be turned on and the third switching transistor Q3 may be turned off. The third voltage VLX has the voltage level identical or substantially identical to the voltage level of the flying capacitor voltage VCF of the third capacitor CFLY, and the inductor current IL increases.

As described above with reference to FIGS. 5A and 5B, switching operations of the first switching transistor Q1, the second switching transistor Q2, the third switching transistor Q3, and the fourth switching transistor Q4 may be repeatedly performed, and accordingly, an output voltage bucked from the input voltage (e.g., the first voltage VBYP) may be output through the sixth node N6. Here, a voltage drop ratio may be determined according to a duty ratio D.

In the buck mode, the inductor current IL flows in a first direction (or a forward direction), and in the boost mode, the inductor current IL flows in a second direction (or a backward direction) different from the first direction. In the buck-boost mode, the inductor current IL may flow in two directions. In the buck-boost mode, the controller 120 may be configured to control the bidirectional switching converter 110 to perform the switching operation according to the buck mode or the boost mode. According to a direction of the inductor current IL, the bidirectional switching converter 110 may perform buck converting or boost converting. The controller 120 may be configured to control the flying capacitor voltage VCF of the third capacitor CFLY to be a target voltage (e.g., ½*VBYP) when the bidirectional switching converter 110 performs the buck converting operation and the boost converting operation, by adjusting the period in which each of the first switching voltage VG1, the second switching voltage VG2, the third switching voltage VG3, and the fourth switching voltage VG4 has the active level and the inactive level according to the direction of the inductor current IL.

The inductor current IL usually flows in a direction according to a switching mode. When polarity of the inductor current IL changes in a particular switching mode, the charger IC 100 may be damaged. In a two-level converter, the polarity of the inductor current IL may be usually maintained in a particular switching mode. However, unlike the two-level converter, in a three-level converter, the polarity of the inductor current IL may also be changed according to a charge amount of the flying capacitor voltage VCF in a particular switching mode. For example, when the flying capacitor voltage VCF is overcharged or overdischarged, the polarity of the inductor current IL may be changed in a certain period between the time point to and the time point t1, a particular period between the time point t2 and the time point t3, or the like, as illustrated in FIGS. 5A and 5B. To prevent or reduce the change in the polarity of the inductor current IL according to the charge amount of the flying capacitor voltage VCF, a bidirectional current sensor configured to continuously sense a zero-current and an over-current may be included in the controller 120.

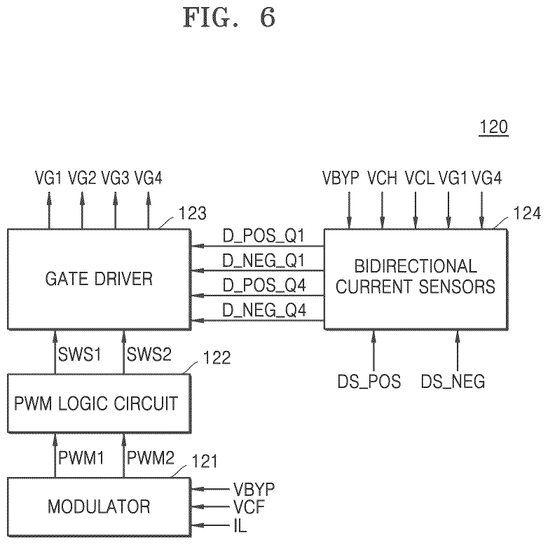

FIG. 6 is a block diagram of the controller 120 according to some example embodiments.

Referring to FIG. 6, the controller 120 may include a modulator 121, a pulse width modulation (PWM) logic circuit 122, a gate driver 123, and a plurality of bidirectional current sensors 124. The controller 120 corresponds to the charging controller 120 of FIG. 1.

The modulator 121 may be configured to generate a first PWM signal PWM1 and a second PWM signal PWM2 based on the voltages (e.g., the first voltage VBYP, the flying capacitor voltage VCF) provided from the bidirectional switching converter 110 and a sensing current (e.g., the inductor current IL).

The PWM logic circuit 122 may be configured to output a first switching signal SWS1 and a second switching signal SWS2, based on the first PWM signal PWM1 and the second PWM signal PWM2.

The gate driver 123 may be configured to generate the first switching voltage VG1, the second switching voltage VG2, the third switching voltage VG3, and the fourth switching voltage VG4, based on the first switching signal SWS1 and the second switching signal SWS2.

The gate driver 123 may be configured to generate the first switching voltage VG1 by converting a voltage level of the first switching signal SWS1, invert the first switching signal SWS1, and generate the fourth switching voltage VG4 by converting a voltage level of the first switching signal SWS1 that has been inverted.

The gate driver 123 may be configured to generate the second switching voltage VG2 by converting a voltage level of the second switching signal SWS2, invert the second switching signal SWS2, and generate the third switching voltage VG3 by converting a voltage level of the second switching signal SWS2 that has been inverted.

In some example embodiments, the gate driver 123 may be configured to control the first switching voltage VG1, the second switching voltage VG2, the third switching voltage VG3, and the fourth switching voltage VG4 based on a first detection signal D_POS_Q1, a second detection signal D_NEG_Q1, a third detection signal D_POS_Q4, and a fourth detection signal D_NEG_Q4. For example, the gate driver 123 may be configured to generate or prevent (or reduce) the first switching voltage VG1, the second switching voltage VG2, the third switching voltage VG3, and the fourth voltage based on the first detection signal D_POS_Q1, the second detection signal D_NEG_Q1, the third detection signal D_POS_Q4, and the fourth detection signal D_NEG_Q4 provided from the plurality of bidirectional current sensors 124.

For example, when a magnitude of the inductor current IL (or the first switching current I_IN1 and the second switching current I_IN2) decreases to ‘O’ in the buck mode, the plurality of bidirectional current sensors 124 may generate the second detection signal D_NEG_Q1 or the fourth detection signal D_NEG_Q4 each having an active level, and the gate driver 123 may prevent or reduce generation of the first switching voltage VG1, the second switching voltage VG2, the third switching voltage VG3, and the fourth switching voltage VG4. Accordingly, the inductor current IL may be prevented or reduced from flowing in the backward direction (e.g., a direction from the sixth node N6 to the third node N3). Alternatively, when the magnitude of the inductor current IL increases to a certain value in the buck mode, the plurality of bidirectional current sensors 124 may generate the first detection signal D_POS_Q1 or the third detection signal D_POS_Q4 each having an active level, and the gate driver 123 may prevent or reduce the generation of the first switching voltage VG1, the second switching voltage VG2, the third switching voltage VG3, and the fourth switching voltage VG4. Accordingly, the inductor current IL flowing in the forward direction (e.g., a direction from the third node N3 to the sixth node N6) from being an over-current.

For example, when the magnitude of the inductor current IL decreases to ‘O’ in the boost mode, the plurality of bidirectional current sensors 124 may generate the first detection signal D_POS_Q1 or the third detection signal D_POS_Q4 each having the active level. Accordingly, the inductor current IL may be prevented or reduced from flowing in the forward direction. Alternatively, when the magnitude of the inductor current IL increases to a certain value in the boost mode, the plurality of bidirectional current sensors 124 may generate the second detection signal D_NEG_Q1 or the fourth detection signal D_NEG_Q4 each having the active level. Accordingly, the inductor current IL flowing in the backward direction may be prevented or reduced from being an over-current.

For example, when the magnitude of the inductor current IL flowing in the forward direction increases to a certain value in the buck-boost mode, the plurality of bidirectional current sensors 124 may generate the first detection signal D_POS_Q1 or the third detection signal D_POS_Q4 each having an active level. Accordingly, an over-current of the inductor current IL flowing in the forward direction may be prevented or reduced. Alternatively, when the magnitude of the inductor current IL flowing in the backward direction increases to a certain value in the buck-boost mode, the plurality of bidirectional current sensors 124 may generate the second detection signal D_NEG_Q1 or the fourth detection signal D_NEG_Q4 each having an active level. Accordingly, the over-current of the inductor current IL flowing in the backward direction may be prevented or reduced.

The plurality of bidirectional current sensors 124 may be configured to generate the first detection signal D_POS_Q1, the second detection signal D_NEG_Q1, the third detection signal D_POS_Q4, and the fourth detection signal D_NEG_Q4 based on a plurality of voltages (e.g., the first voltage VBYP, a second voltage VCH, and/or the voltage VCL), the first switching voltage VG1 to the fourth switching voltage VG4, and the reference voltages.

In some example embodiments, the plurality of bidirectional current sensors 124 may include two bidirectional current sensors, a first bidirectional current sensor may be configured to sense the first switching current I_IN1 of the first switching transistor Q1, and a second bidirectional current sensor may be configured to sense the second switching current I_IN2 of the fourth switching transistor Q4.

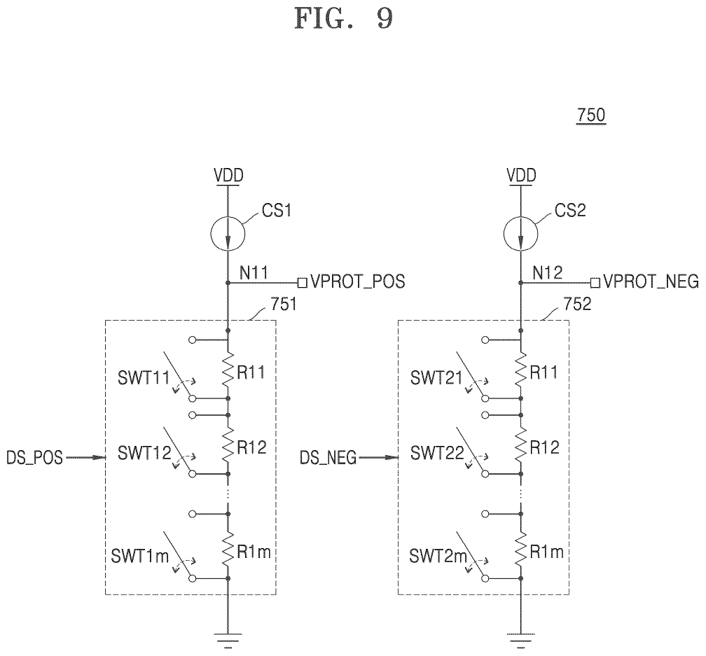

In some example embodiments, the plurality of bidirectional current sensors 124 may be configured to receive a first digital signal DS_POS and a second digital signal DS_NEG. The first digital signal DS_POS and the second digital signal DS_NEG may be generated by the application processor 400 illustrated in FIG. 1. The plurality of bidirectional current sensors 124 may be configured to set voltage levels of the reference voltages based on the first digital signal DS_POS and the second digital signal DS_NEG. When logical values of the first digital signal DS_POS or logical values of the second digital signal DS_NEG change, the voltage level of the reference voltage may change. Some example embodiments in which the voltage level of the reference voltage changes will be described later with reference to FIG. 9.

According to some example embodiments, by connecting a bidirectional current sensor capable of performing both of over-current detection and zero-current detection to a switching element, switching modes may be seamlessly transited, and during seamless mode transition, the bidirectional current sensor may continuously operate and continuously protect the inductor current IL.

According to some example embodiments, by implementing the bidirectional current sensor for continuously detecting the zero-current and the over-current, the inductor current IL may be continuously prevented or reduced even when the flying capacitor voltage VCF included in the charger IC 100 is overcharged or overdischarged, and damage to a switching element, the charger IC 100, and the electronic device 10 including the charger IC 100 may be reduced.

According to some example embodiments, by using two bidirectional current sensors capable of performing both of over-current detection and zero-current detection in the charger IC 100, sizes of chips in the charger IC 100 may be reduced.

FIG. 7 is a circuit diagram of a first bidirectional current sensor 700 according to some example embodiments.

Referring to FIG. 7, the first bidirectional current sensor 700 may include a sensing circuit 710, an amplification circuit 720, a sensing voltage generation circuit 730, and a comparison circuit (or detection circuit) 740.

The sensing circuit 710 may be configured to sense the first switching current I_IN1 flowing the first switching transistor Q1 that is turned on. The sensing circuit 710 may be connected to the first node N1 connected to an end of the first switching transistor Q1 and the second node N2 connected to another end of the first switching transistor Q1. The first voltage VBYP may be applied to the first node N1, and the second voltage VCH may be applied to the second node N2. The first switching transistor Q1 that is turned on may correspond to a turn-on resistor and may have a resistance of the turn-on resistor. That is, the resistance of the turn-on resistor may be set in response to turning on the first switching transistor Q1.

The sensing circuit 710 may be configured to sense the first voltage VBYP and the second voltage VCH based on the first switching voltage VG1 and output a first bias current Ib1, a second bias current Ib2, a first offset current IOFST1, and a second offset current IOFST2.

In some example embodiments, the sensing circuit 710 may include a delay circuit 711, a level shifter 712, a first sensing module 713, a second sensing module 714, a third sensing module 715, and a fourth sensing module 716.

The delay circuit 711 may be configured to receive the first switching voltage VG1 and delay the first switching voltage VG1. For example, the delay circuit 711 may be configured to delay a time point at which the first switching voltage VG1 has an active level. The delay circuit 711 may be configured to output a delay enable signal D_EN.

The level shifter 712 may be configured to receive the delay enable signal D_EN and output a sensing control signal SCS based on the delay enable signal D_EN. For example, the level shifter 712 may be configured to output the sensing control signal SCS having an active level, in response to an active level of the delay enable signal D_EN. The sensing control signal SCS may be commonly provided to the first sensing module 713 to the fourth sensing module 716.

The first sensing module 713 to the fourth sensing module 716 may each include at least one sensing element. In some example embodiments, the first sensing module 713 may include a first sensing transistor SS1 and a second sensing transistor SS2. The second sensing module 714 may include a third sensing transistor SS3, a fourth sensing transistor SS4, and a fifth sensing transistor SS5. The third sensing module 715 may include a sixth sensing transistor SS6, a seventh sensing transistor SS7, and an eighth sensing transistor SS8. The fourth sensing module 716 may include a ninth sensing transistor SS9 and a tenth sensing transistor SS10. The first sensing transistor SS1 to the tenth sensing transistor SS10 included in the first sensing module 713 to the fourth sensing module 716 according to some example embodiments may be turned on in response to the sensing control signal SCS having the active level. The sensing transistors included in the first sensing module 713 to the fourth sensing module 716 may be connected in series. In FIG. 7, the sensing transistors may be implemented as N-type transistors or N-channel metal-oxide-semiconductor field effect transistor (NMOSFET), however, example embodiments are not limited thereto, and according to some example embodiments, the sensing transistors may be implemented as P-type transistors.

The first sensing module 713 and the third sensing module 715 may be connected to the first node N1, and the second sensing module 714 and the fourth sensing module 716 may be connected to the second node N2. The first sensing module 713 may be further connected to a seventh node N7, and the fourth sensing module 716 may be further connected to an eighth node N8.

When the first sensing transistor SS1 and the second sensing transistor SS2 included in the first sensing module 713 are turned on, the first node N1 and the seventh node N7 may be electrically connected to each other, and the first offset current IOFST1 and the first bias current Ib1 may be output from the seventh node N7. The first sensing transistor SS1 and the second sensing transistor SS2 those are turned on may have a first resistance of a resistor. When the third sensing transistor SS3 to the fifth transistor SS5 included in the second sensing module 714 are turned on, the second node N2 and the amplification circuit 720 may be electrically connected to each other, and the second bias current Ib2 may be output. The third sensing transistor SS3, the fourth sensing transistor SS4, and the fifth sensing transistor SS5 those are turned on may have a second resistance of a resistor. In some example embodiments, sizes of the first sensing module 713 and the second sensing module 714 may be set and sensing transistors in the number corresponding to the sizes may be connected in series, such that a ratio of the first resistance and the second resistance is 1:N. N may include an arbitrary number greater than 1. In some example embodiments, the first resistance and the second resistance may be set in response to turning on the first switching transistor Q1.

When the sixth sensing transistor SS6 to the eighth sensing transistor SS8 included in the third sensing module 715 are turned on, the first node N1 and the amplification circuit 720 may be electrically connected to each other, and the second bias current Ib2 may be output. The sixth sensing transistor SS6 to the eighth sensing transistor SS8 those are turned on may have the second resistance of the resistor. When the ninth sensing transistor SS9 and the tenth sensing transistor SS10 included in the fourth sensing module 716 are turned on, the first node N1 and the seventh node N7 may be electrically connected to each other, and the second offset current IOFST2 and the first bias current Ib1 may be output from the eighth node N8. The first sensing transistor SS1 and the second sensing transistor SS2 those are turned on may have the first resistance of the resistor. In some example embodiments, the ratio of the first resistance and the second resistance may be 1:N. In some example embodiments, the first resistance and the second resistance may be set in response to turning on the first switching transistor Q1.

The amplification circuit 720 may be configured to receive the first bias current Ib1 and the second bias current Ib2 from the sensing circuit 710. The amplification circuit 720 may be configured to output a first amplification voltage Va1 and a second amplification voltage Va2 based on the first bias current Ib1 and the second bias current Ib2. In some example embodiments, the amplification circuit 720 may be implemented as a common gate amplifier. For example, the amplification circuit 720 may be configured to amplify a difference between the first bias current Ib1 and the second bias current Ib2 and output the first amplification voltage Va1 and the second amplification voltage Va2. The amplification circuit 720 may include a first input terminal to a fourth input terminal, a first output terminal OUT1, and a second output terminal OUT2. The first bias current Ib1 may be input to the first input terminal and the fourth input terminal of the amplification circuit 720, the second bias current Ib2 may be input to the second input terminal and the third input terminal of the amplification circuit 720, the first amplification voltage Va1 may be output from the first output terminal OUT1 of the amplification circuit 720, and the second amplification voltage Va2 may be output from the second amplification voltage second output terminal OUT2 of the amplification circuit 720.

The sensing voltage generation circuit 730 may be configured to receive the first offset current IOFST1, the second offset current IOFST2, the first amplification voltage Va1, and the second amplification voltage Va2. The sensing voltage generation circuit 730 may be configured to output a first sensing voltage VSEN_POS_Q1 and a second sensing voltage VSEN_NEG_Q1 corresponding to the first switching current I_IN1, based on the first offset current IOFST1, the second offset current IOFST2, the first amplification voltage Va1, and the second amplification voltage Va2.

In some example embodiments, the sensing voltage generation circuit 730 may include a first transistor TR1, a first resistor RG1, a second transistor TR2, and a second resistor RG2. An end of the first transistor TR1 may be connected to the seventh node N7, another end of the first transistor TR1 may be connected to a ninth node N9, and the first amplification voltage Va1 may be provided to a first gate electrode of the first transistor TR1. The first transistor TR1 may be turned on in response to the first amplification voltage Va1 having the active level, and the seventh node N7 and the ninth node N9 may be electrically connected to each other. The first resistor RG1 may be connected between the ninth node N9 and a ground. The first sensing voltage VSEN_POS_Q1 may be applied to the ninth node N9. An end of the second transistor TR2 may be connected to the eighth node N8, another end of the second transistor TR2 may be connected to a tenth node N10, and the second amplification voltage Va2 may be provided to a second gate electrode of the second transistor TR2. The second transistor TR2 may be turned on in response to the second amplification voltage Va2 having the active level, and the eighth node N8 and the tenth node N10 may be electrically connected to each other. The second resistor RG2 may be connected between the tenth node N10 and the ground. The second sensing voltage VSEN_NEG_Q1 may be applied to the tenth node N10. In some example embodiments, the first resistor RG1 and the second resistor RG2 may have a same resistance.

The comparison circuit 740 may be configured to receive a first reference voltage VPROT_POS, a second reference voltage VPROT_NEG, the first sensing voltage VSEN_POS_Q1, and the second sensing voltage VSEN_NEG_Q1, and output the first detection signal D_POS_Q1 and the second detection signal D_NEG_Q1, based on the first reference voltage VPROT_POS, the second reference voltage VPROT_NEG, the first sensing voltage VSEN_POS_Q1, and the second sensing voltage VSEN_NEG_Q1. The first detection signal D_POS_Q1 and the second detection signal D_NEG_Q1 may indicate whether the zero-current and the over-current have been detected for the first switching current I_IN1 (or the inductor current IL). For example, in the buck mode, the first detection signal D_POS_Q1 may indicate whether the over-current has been detected, and the second detection signal D_NEG_Q1 may indicate whether the zero-current has been detected. For example, in the boost mode, the first detection signal D_POS_Q1 may indicate whether the zero-current has been detected, and the second detection signal D_NEG_Q1 may indicate whether the over-current has been detected. As described above, according to switching modes, a detection signal may include an over-current detection signal indicating whether the over-current has been detected or a zero-current detection signal indicating whether the zero-current has been detected.

In some example embodiments, the comparison circuit 740 may include a first comparator (or a first detector) 741 and a second comparator (or a second detector) 742. The first comparator 741 may be configured to receive the first reference voltage VPROT_POS and the first sensing voltage VSEN_POS_Q1, compare the first reference voltage VPROT_POS and the first sensing voltage VSEN_POS_Q1, and output the first detection signal D_POS_Q1 indicating a result of the comparison. That is, the first comparator 741 may determine the first detection signal D_POS_Q1 based on the first reference voltage VPROT_POS and the first sensing voltage VSEN_POS_Q1. When a magnitude of the first sensing voltage VSEN_POS_Q1 is greater or equal to a magnitude of the first reference voltage VPROT_POS, the first detection signal D_POS_Q1 may have an active level (e.g., a logic high level). When the magnitude of the first sensing voltage VSEN_POS_Q1 is less than the magnitude of the first reference voltage VPROT_POS, the first detection signal D_POS_Q1 may have an inactive level (e.g., a logic low level). The second comparator 742 may be configured to receive the second reference voltage VPROT_NEG and the second sensing voltage VSEN_NEG_Q1, compare the second reference voltage VPROT_NEG and the second sensing voltage VSEN_NEG_Q1, and output the second detection signal D_NEG_Q1 indicating a result of the comparison. That is, the second comparator 742 may determine the second detection signal D_NEG_Q1 based on the second reference voltage VPROT_NEG and the second sensing voltage VSEN_NEG_Q1. When a magnitude of the second sensing voltage VSEN_NEG_Q1 is equal to a magnitude of the second reference voltage VPROT_NEG or greater, the second detection signal D_NEG_Q1 may have an active level, and when the magnitude of the second sensing voltage VSEN_NEG_Q1 is less than the magnitude of the second reference voltage VPROT_NEG, the second detection signal D_NEG_Q1 may have an inactive level.

According to some example embodiments, by implementing a bidirectional current sensor capable of performing both of over-current detection and zero-current detection in the charger IC 100, a layout area of the charger IC 100 may be reduced.

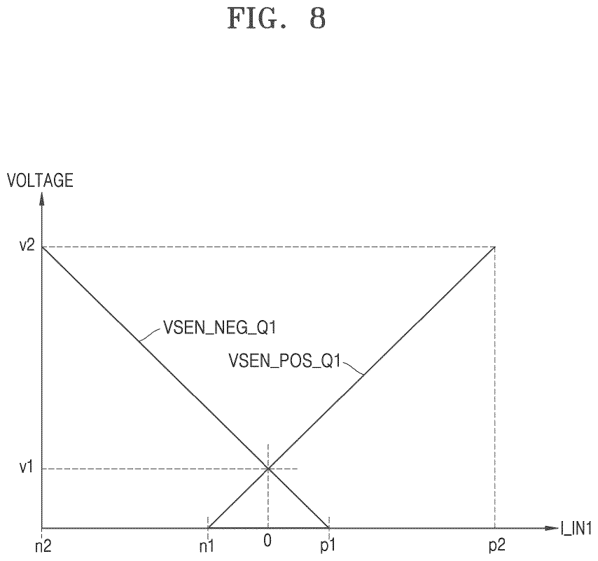

FIG. 8 is a graph illustrating a relationship between a sensing voltage and a switching current of the first bidirectional current sensor 700 illustrated in FIG. 7.

Referring to FIGS. 7 and 8, the first sensing voltage VSEN_POS_Q1 and the first switching current I_IN1 detected from the first bidirectional current sensor 700 may have a linear relationship in a certain section. For example, the first sensing voltage VSEN_POS_Q1 and the first switching current I_IN1 may have a relationship as Equation 1 below.

$${V}_{SEN \_ POS} = \frac{[ \frac{{R}_{ON}}{{R}_{SNS}} {I}_{IN 1} + N \times {I}_{b 2} - {I}_{b 1} ] {R}_{GAIN}}{2} \qquad [ Equation 1 ]$$

In Equation 1, V_{SEN_POS} indicates a voltage level of the first sensing voltage VSEN_POS_Q1, IIN1 indicates a value of the first switching current I_IN1, RON indicates a resistance of a turn-on resistor corresponding to the first switching transistor Q1 that is been turned on, RSNS indicates a first resistance of the first sensing module 713 (e.g., a first resistance of a sensing resistor corresponding to the first sensing transistor SS1 and the second sensing transistor SS2 those are turned on), N×RSNS indicates a second resistance of the second sensing module 714 (e.g., a ratio of the first resistance and the second resistance is 1:N), N indicates a ratio of the second resistance to the first resistance (e.g., the second resistance/the first resistance), Ib1 indicates a value of the first bias current Ib1, 1b2 indicates a value of the second bias current Ib2, and RGAIN indicates a resistance of the first resistor RG1 or a resistance of the second resistor RG2.

According to Equation 1 and a sensing range of the first sensing voltage VSEN_POS_Q1, a sensing range of the first switching current I_IN1 that may be sensed based on the first sensing voltage VSEN_POS_Q1 may include a n1 value to a p2 value. Here, it is assumed that n1 and n2 are values less than 0, p1 and p2 are values greater than 0, an absolute value of n1 is less than an absolute value of n2, an absolute value of p1 is less than an absolute value of p2, and the absolute value of n1 and the absolute value of p1 are equal to each other.

The first sensing voltage VSEN_POS_Q1 may have linear characteristics for the first switching current I_IN1 in the range from the n1 value to the p2 value. Accordingly, the first sensing voltage VSEN_POS_Q1 may be used for an over-current detection function (or an over-current prevention function) in the buck converting operation, and may be used for a zero-current detection function (or a zero-current prevention function) in the boost converting operation.

The second sensing voltage VSEN_NEG_Q1 and the first switching current I_IN1 detected from the first bidirectional current sensor 700 may have a linear relationship in a certain period. For example, the second sensing voltage VSEN_NEG_Q1 and the first switching current I_IN1 may have a relationship as Equation 2 below.

$${V}_{SEN \_ NEG} = \frac{[ - \frac{{R}_{ON}}{{R}_{SNS}} I\_IN 1 + N \times Ib 1 - Ib 1 ] {R}_{GAIN}}{2} \qquad [ Equation 2 ]$$

In Equation 2, V_{SEN_NEG} indicates a voltage level of the second sensing voltage VSEN_NEG_Q1, RSNS indicates a first resistance of the fourth sensing module 716, N×RSNS indicates a second resistance of the third sensing module 715, N indicates the ratio of the second resistance to the first resistance (e.g., the second resistance/the first resistance), Ib1 indicates a value of the first bias current Ib1, 1b2 indicates a value of the second bias current Ib2, RGAIN indicates the resistance of the first resistor RG1 or the resistance of the second resistor RG2. Descriptions regarding parameters in Equation 2 same as those in Equation 1 will be omitted.

According to Equation 2 and a sensing range of the second sensing voltage VSEN_NEG_Q1, the sensing range of the first switching current I_IN1 that may be sensed based on the second sensing voltage VSEN_NEG_Q1 may include the n2 value to the p1 value. Here, it is assumed that n1 and n2 are values less than 0, p1 and p2 are values greater than 0, the absolute value of n1 is less than the absolute value of n2, the absolute value of p1 is less than the absolute value of p2, and the absolute value of n1 and the absolute value of p1 are equal to each other.

The second sensing voltage VSEN_NEG_Q1 may have linear characteristics for the first switching current I_IN1 in the range from the n2 value to the p1 value. Accordingly, the second sensing voltage VSEN_NEG_Q1 may be used for the over-current detection function (or the zero-current prevention function) in the buck converting operation, and may be used for the over-current detection function (or the over-current prevention function) in the boost converting operation.

A voltage level of the first reference voltage VPROT_POS and a voltage level of the second reference voltage VPROT_NEG may be set according to switching modes. For example, in the buck mode, the voltage level of the first reference voltage VPROT_POS may be set as a v2 value shown in FIG. 8, and the voltage level of the second reference voltage VPROT_NEG may be set as a v1 value shown in FIG. 8. In this case, in the buck mode, the first reference voltage VPROT_POS may be used for sensing the over-current, and the second reference voltage VPROT_NEG may be used for sensing the zero-current. For example, in the boost mode, the voltage level of the first reference voltage VPROT_POS may be set as the v1 value shown in FIG. 8, and the voltage level of the second reference voltage VPROT_NEG may be set as the v2 value shown in FIG. 8. Here, in the boost mode, the first reference voltage VPROT_POS may be used for sensing the zero-current, and the second reference voltage VPROT_NEG may be used for sensing the over-current. For example, in the buck-boost mode, the voltage level of the first reference voltage VPROT_POS and the voltage level of the second reference voltage VPROT_NEG each may be set as the v2 value shown in FIG. 8. In this case, in the buck-boost mode, the first reference voltage VPROT_POS and the second reference voltage VPROT_NEG may be used for sensing the over-current.

According to Equation 1, when the voltage level of the first sensing voltage VSEN_POS_Q1 is equal to the voltage level of the first reference voltage VPROT_POS or higher, the first detection signal D_POS_Q1 may have the active level (e.g., the logic high level). According to Equation 2, when the voltage level of the second sensing voltage VSEN_NEG_Q1 is equal to the voltage level of the second reference voltage VPROT_NEG or higher, the second detection signal D_NEG_Q1 may have the active level (e.g., the logic high level).

FIG. 9 is a circuit diagram of an adjustment circuit 750 included in the first bidirectional current sensor 700 illustrated in FIG. 7.

Referring to FIG. 9, in some example embodiments, the first bidirectional current sensor 700 may further include the adjustment circuit 750 in addition to a configuration illustrated in FIG. 7.

The adjustment circuit 750 may include the first digital signal DS_POS and the second digital signal DS_NEG. The first digital signal DS_POS and the second digital signal DS_NEG may be generated by the application processor 400. The first digital signal DS_POS and the second digital signal DS_NEG may each have m bits, and m may include a natural number, and for example may be 4 or greater, but example embodiments are not limited thereto. The adjustment circuit 750 may be configured to set the voltage levels of the first reference voltage VPROT_POS and the second reference voltage VPROT_NEG based on the first digital signal DS_POS and the second digital signal DS_NEG. The first reference voltage VPROT_POS and the second reference voltage VPROT_NEG may vary according to switching modes.

In some example embodiments, the adjustment circuit 750 may include a first current source CS1, a first resistor selector 751, a second current source CS2, and a second resistor selector 752. The first current source CS1 and the second current source CS2 may be configured to output a first current and a second current based on a supply voltage VDD. The first resistor selector 751 may include m switches SWT11, SWT12, . . . , SWTIm and m resistors R11, R12, . . . , R1m. The first digital signal DS_POS may have m bits, and a logical value of each bit may be applied as a signal for turning on or turning off each of the m switches SWT11, SWT12, . . . , SWTIm. The second resistor selector 752 may include m switches SWT21, SWT22, . . . , SWT2m and m resistors R21, R22, . . . , R2m. The second digital signal DS_NEG may have m bits, and a logical value of each of the m bits may be applied as a signal for turning on or turning off each of the m switches SWT21, SWT22, . . . , SWT2m.

FIG. 10 is a circuit diagram of a second bidirectional current sensor 800 according to some example embodiments.

Referring to FIG. 10, the second bidirectional current sensor 800 may include a sensing circuit 810, an amplification circuit 820, a sensing voltage generation circuit 830, and a comparison circuit (or detection circuit) 840. The second bidirectional current sensor 800 may further include an adjustment circuit identical or substantially identical to the adjustment circuit 750 illustrated in FIG. 9. In some example embodiments, the adjustment circuit 750 illustrated in FIG. 9 may be included in each of the first bidirectional current sensor 700 of FIG. 7 and the second bidirectional current sensor 800 of FIG. 10, but example embodiments are not limited thereto, and in some example embodiments, the adjustment circuit 750 illustrated in FIG. 9 may be implemented once, and the first reference voltage VPROT_POS and the second reference voltage VPROT_NEG may be commonly provided respectively to the first bidirectional current sensor 700 and the second bidirectional current sensor 800.

Descriptions regarding the sensing circuit 810 and the sensing voltage generation circuit 830 are similar to descriptions regarding the sensing circuit 710 with reference to FIG. 7, and descriptions regarding the amplification circuit 820 and the comparison circuit 840 are identical or substantially identical to descriptions regarding the amplification circuit 720 with reference to FIG. 7, and therefore, the descriptions will not be repeatedly given.

The sensing circuit 810 may be configured to sense the second switching current I_IN2 flowing through the fourth switching transistor Q4 that is turned on. The sensing circuit 710 may be connected to the fourth node N4 and the fifth node N5. The fourth switching transistor Q4 that is turned on may correspond to a turn-on resistor and may have a resistance of the turn-on resistor. In some example embodiments, the sensing circuit 710 may include a delay circuit 811, a level shifter 812, a first sensing module 813 to a fourth sensing module 816. A ratio of resistances between the first sensing module 813 and the second sensing module 814 may be 1:N. In addition, a ratio of resistances between the third sensing module 815 and the fourth sensing module 816 may be N:1.

In some example embodiments, the sensing voltage generation circuit 830 may include a first transistor TR1 to a sixth transistor TR6, a first resistor RG1, and a second resistor RG2. The first transistor TR1, the second transistor TR2, the first resistor RG1, and the second resistor RG2 are identical or substantially identical to those described with reference to FIG. 7. The third transistor TR3 and the fourth transistor T4 may be connected in series, gate electrodes of the third transistor TR3 and the fourth transistor TR4 may be connected to each other and to a node to which the third sensing voltage VSEN_POS_Q4 is applied. The fifth transistor TR5 and the sixth transistor TR6 may be connected in series, gate electrodes of the fifth transistor TR5 and the sixth transistor TR6 may be connected to each other and to a node to which the fourth sensing voltage VSEN_NEG_Q4 is applied.

The comparison circuit 840 may be configured to receive the first reference voltage VPROT_POS, the second reference voltage VPROT_NEG, the third sensing voltage VSEN_POS_Q4, and the fourth sensing voltage VSEN_NEG_Q4 and output the third detection signal D_POS_Q4 and the fourth detection signal D_NEG_Q4. The third detection signal D_POS_Q4 and the fourth detection signal D_NEG_Q4 may correspond to the first detection signal D_POS_Q1 and the second detection signal D_NEG_Q1. In some example embodiments, the comparison circuit 840 may include a first comparator (or a first detector) 841 and a second comparator (or a second detector) 842. The first comparator 841 may be configured to compare the first reference voltage VPROT_POS and the third sensing voltage VSEN_POS_Q4 and output the third detection signal D_POS_Q4 indicating a result of the comparison. The second comparator 842 may be configured to compare the second reference voltage VPROT_NEG and the fourth sensing voltage VSEN_NEG_Q4 and output the fourth detection signal D_NEG_Q4 indicating a result of the comparison. That is, the first and second comparators 841 and 842 may be similar to the first and second comparators 741 and 742, and determine the specific detection signals based on the specific reference voltage and specific sensing voltage.

A relation between the third sensing voltage VSEN_POS_Q4 and the second switching current I_IN2 may be based on an equation identical or substantially identical to Equation 1 described above with reference to FIG. 8. In this case, RON indicates a resistance of a turn-on resistor corresponding to the fourth switching transistor Q4 that is turned on, RSNS indicates a first resistance of the first sensing module 813, and N×RSNS indicates a second resistance of the second sensing module 814. A relation between the fourth sensing voltage VSEN_NEG_Q4 and the second switching current I_IN2 may be based on an equation identical or substantially identical to Equation 2 described above with reference to FIG. 8. In this case, RSNS indicates a first resistance of the fourth sensing module 816, and N×RSNS indicates a second resistance of the third sensing module 815. The third sensing voltage VSEN_POS_Q4, the fourth sensing voltage VSEN_NEG_Q4, and the second switching current I_IN2 may have a linear relationship in a certain section, similar to FIG. 8.

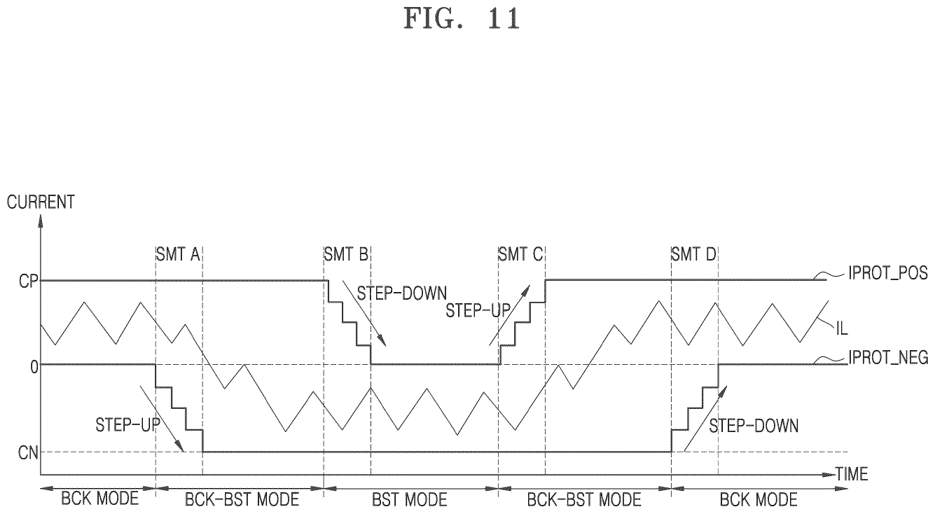

FIG. 11 illustrates a graph indicating a relationship between the inductor current IL and reference currents (e.g., a first reference current IPROT_POS and a second reference current IPROT_NEG) varying when the switching modes are changed.

Referring to FIG. 11, the first reference current IPROT_POS may be a current corresponding to the first reference voltage VPROT_POS, and the second reference current IPROT_NEG may be a current corresponding to the second reference voltage VPROT_NEG. Setting values of the reference currents to be specific values is equal to setting the voltage levels of the reference voltages to be specific levels. In FIG. 11, ‘CP’ and ‘CN’ may indicate arbitrary values having a same absolute value and opposite marks. The inductor current IL may correspond to the first switching current I_IN1 (or the second switching current I_IN2). The inductor current IL may increase or decrease between the first reference current IPROT_POS and the second reference current IPROT_NEG.

In the buck mode BCK MODE, a value of the first reference current IPROT_POS may be set to be ‘CP’, and a value of the second reference current IPROT_NEG may be set to be a certain value (e.g., ‘0’). The inductor current IL may swing between ‘CP’ and ‘0’.

The switching mode may be transited from the buck mode BCK MODE to the buck-boost mode BCK-BST MODE (e.g., as a logical value of the mode signal MD is changed, the switching mode may be transited). A magnitude of the second reference current IPROT_NEG may gradually decrease from the certain value (e.g., ‘0’) to the absolute value of ‘CN’) (refer to ‘Seamless mode transition (SMT) A’ shown in FIG. 11). Even while the value of the second reference current IPROT_NEG changes, the inductor current IL may swing between the first reference current IPROT_POS and the second reference current IPROT_NEG, and the switching mode may be seamlessly transited. That is, seamless mode transition may be available. In the buck-boost mode BCK-BST MODE, the value of the first reference current IPROT_POS may be maintained as ‘CP’, and the inductor current IL may swing.

The switching mode may be transited from the buck-boost mode BCK-BST MODE to the boost mode BST MODE. A magnitude of the first reference current IPROT_POS may gradually decrease from ‘CP’ to the certain value (e.g., ‘0’) (Refer to ‘SMT B’ shown in FIG. 11). Even while the value of the first reference current IPROT_POS changes, the inductor current IL may swing between the first reference current IPROT_POS and the second reference value IPORT_NEG, and seamless mode transition may be available. In the boost mode BST MODE, the value of the second reference current IPROT_NEG is maintained as ‘CN’, and the inductor current IL may swing.

The switching mode may be transited from the boost mode BST MODE to the buck-boost mode BCK-BST MODE, and even while the magnitude of the first reference current IPROT_POS gradually increase from the certain value (e.g., ‘0’) to ‘CP’ (refer to ‘SMT C’ shown in FIG. 11), seamless mode transition may be available.

The switching mode may be transited from buck-boost mode BCK-BST MODE to the buck mode BCK MODE, and even while the magnitude of the second reference current IPROT_NEG decreases from the absolute value of ‘CN’ to the certain value (e.g., ‘0’) (refer to ‘SMT D’ shown in FIG. 11), seamless mode transition may be available.

According to some example embodiments, by gradually changing the reference voltages when the switching mode is transited, discontinuity of a current protection operation may be prevented or reduced, and elements such as switching elements may be protected.

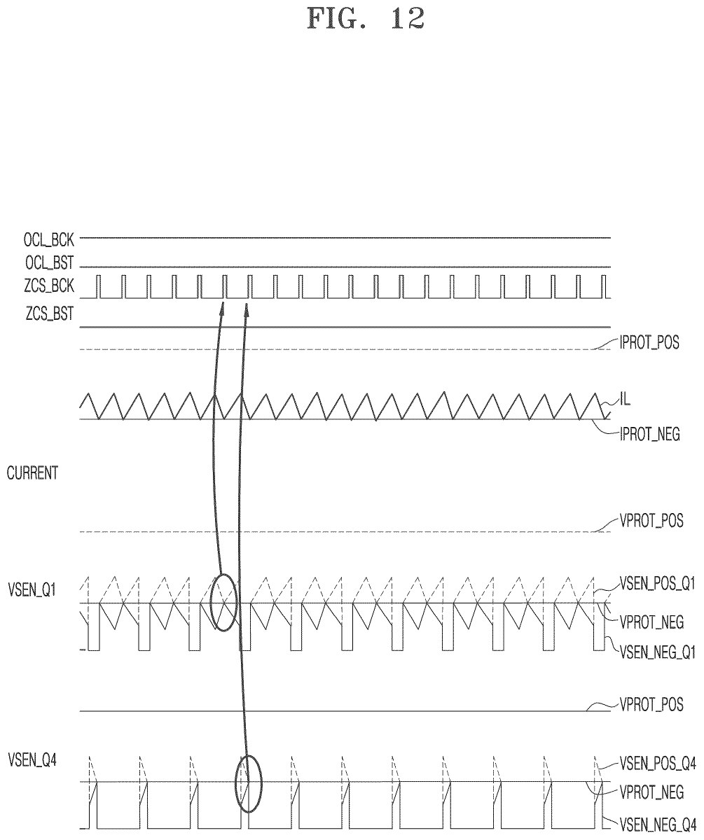

FIGS. 12 to 17 illustrate timing charts of the reference voltages, the sensing voltages, the inductor current, and the detection signals in the switching modes and switching mode transition.

Numerical values shown in FIGS. 12 to 17 are examples for describing some example embodiments, and example embodiments are not limited thereto. In addition, for convenience of explanation, it is assumed that numerical values shown in FIGS. 12 to 17 (and in relation to other figures) include absolute values and may be exact or within a sensing, manufacturing, or other tolerance of, for example, 10 percent. A voltage VSEN_Q1 is a voltage sensed by the first bidirectional current sensor 700, and a voltage VSEN_Q4 is a voltage sensed by the second bidirectional current sensor 800. Signals OCL_BCK and ZCS_BCK correspond to the over-current detection signal and the zero-current detection signal in the buck mode BCK MODE, signals OCL_BST and ZCS_BST may correspond to the over-current detection signal and the zero-current detection signal in the boost mode BST MODE (or a period in the buck-boost mode BCK-BST MODE). The signals OCL_BCK, ZCS_BCK, OCL_BST, and ZCS_BST may correspond to the first detection signal D_POS_Q1, the second detection signal D_NEG_Q1, the third detection signal D_POS_Q4, and the fourth detection signal D_NEG_Q4.

FIG. 12 is a timing chart illustrating some example embodiments in which the zero-current and the over-current are detected in the buck mode BCK MODE shown in FIG. 11. Referring to FIG. 12, when the inductor current IL decreases to the second reference current IPROT_NEG in the buck mode BCK MODE, the second sensing voltage VSEN_NEG_Q1 and/or the fourth sensing voltage VSEN_NEG_Q4 identical or substantially identical to the second reference voltage VPROT_NEG may be sensed. In this case, a zero-current detection signal ZCS_BCK may have an active level (e.g., a logic high level). Meanwhile, the over-current detection operation may be on standby.

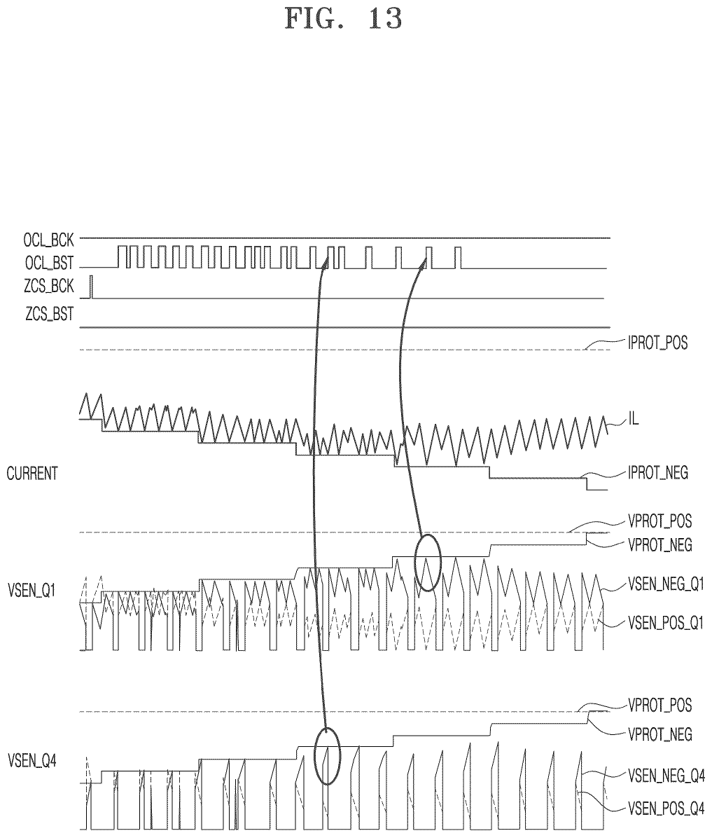

FIG. 13 is a timing chart illustrating some example embodiments in which the zero-current and the over-current are detected in ‘SMT A’ shown in FIG. 11. Referring to FIG. 13, when the switching mode is transited from the buck mode BCK MODE to the buck-boost mode BCK-BST MODE, the magnitude of the second reference voltage VPROT_NEG and the magnitude of the second reference current IPROT_NEG may gradually increase. When the second sensing voltage VSEN_NEG_Q1 and/or the fourth sensing voltage VSEN_NEG_Q4 identical or substantially identical to the second reference voltage VPROT_NEG are/is sensed, the over-current detection signal OCL_BST may have an active level.

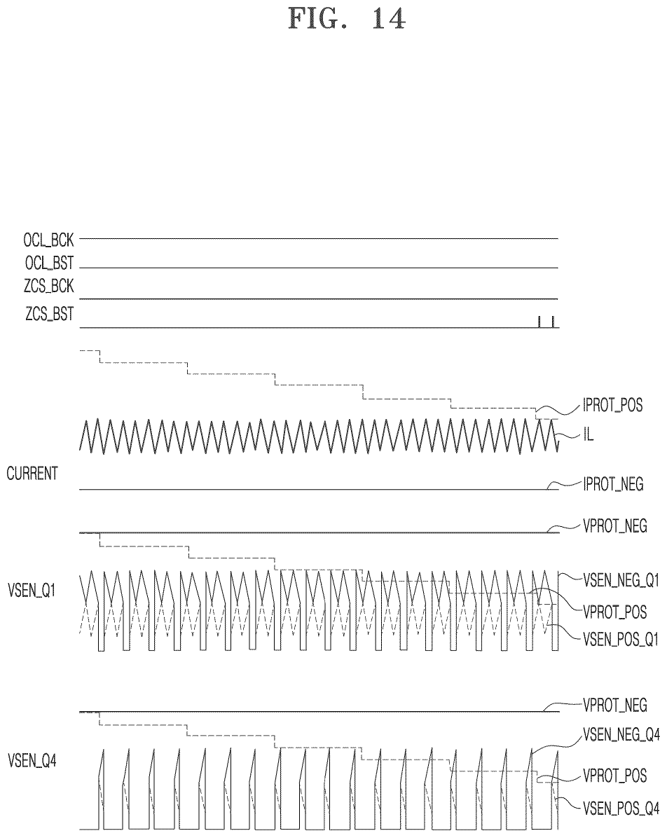

FIG. 14 is a timing chart illustrating some example embodiments in which the zero-current and the over-current are detected in ‘SMT B’ shown in FIG. 11. Referring to FIG. 14, when the switching mode is transited from the buck-boost mode BCK-BST MODE to the boost mode BST MODE, the magnitude of the first reference voltage VPROT_POS and the magnitude of the first reference current IPROT_POS may gradually decrease. When the first sensing voltage VSEN_POS_Q1 and/or the third sensing voltage VSEN_POS_Q4 identical or substantially identical to the first reference voltage VPROT_POS are/is sensed, the zero-current detection signal ZCS_BST may have an active level.

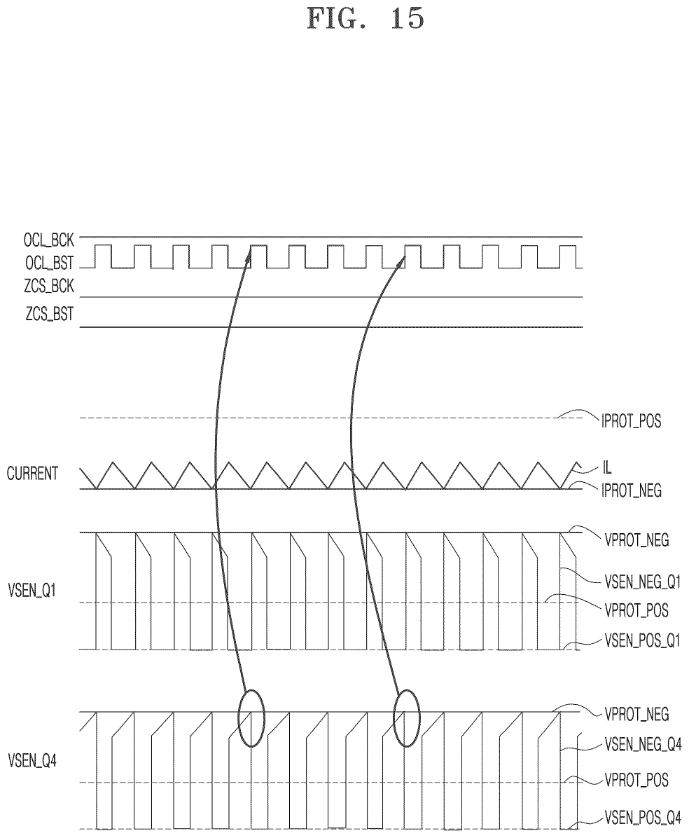

FIG. 15 is a timing chart illustrating some example embodiments in which the zero-current and the over-current are detected in the boost mode BST MODE. Referring to FIG. 15, in the boost mode BST MODE, the inductor current IL may decrease to the second reference current IPROT_NEG. When the second sensing voltage VSEN_NEG_Q1 and/or the fourth sensing voltage VSEN_NEG_Q4 identical or substantially identical to the second reference voltage VPROT_NEG are/is sensed, the over-current detection signal OCL_BST may have the active level.

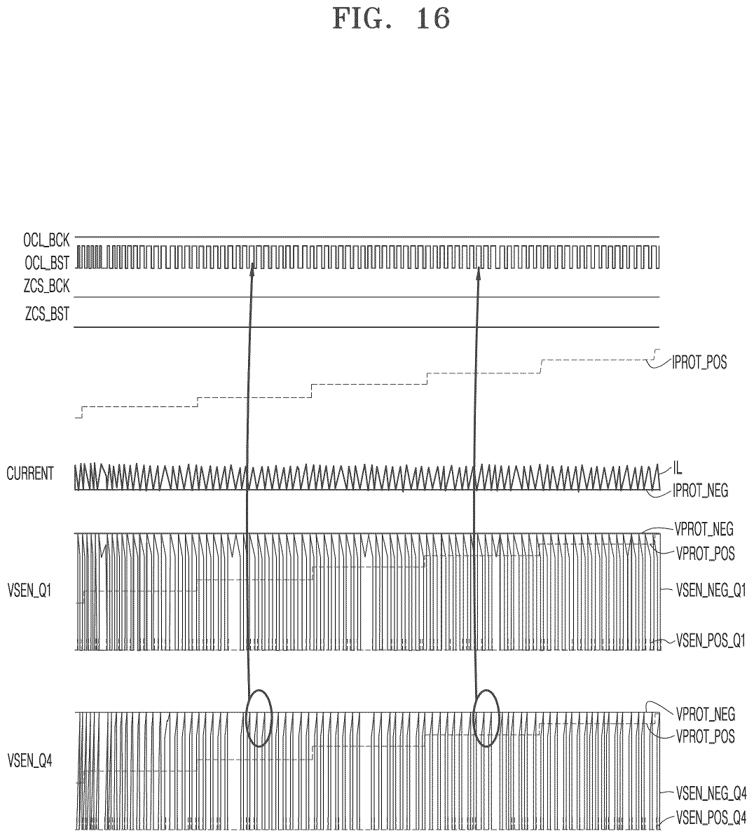

FIG. 16 is a timing chart illustrating some example embodiments in which the zero-current and the over-current are detected in ‘SMT C’ shown in FIG. 11. Referring to FIG. 16, when the switching mode is transited from the boost mode BST MODE to the buck-boost mode BCK-BST MODE, the magnitude of the first reference voltage VPROT_POS and the magnitude of the first reference current IPROT_POS may gradually increase. When the second sensing voltage VSEN_NEG_Q1 and/or the fourth sensing voltage VSEN_NEG_Q4 identical or substantially identical to the second reference voltage VPROT_NEG are/is sensed, the over-current detection signal OCL_BST may have the active level.

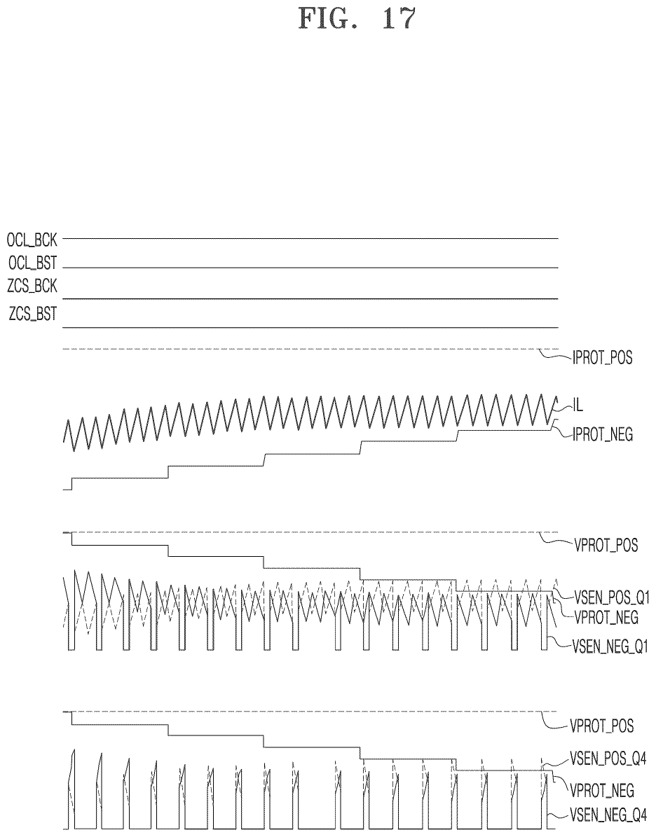

FIG. 17 is a timing chart illustrating some example embodiments in which the zero-current and the over-current are detected in ‘SMT D’ shown in FIG. 11. Referring to FIG. 17, when the switching mode is transited from the buck-boost mode BCK-BST MODE to the buck mode BCK MODE, the magnitude of the second reference voltage VPROT_NEG and the magnitude of the second reference current IPROT_NEG may gradually increase.

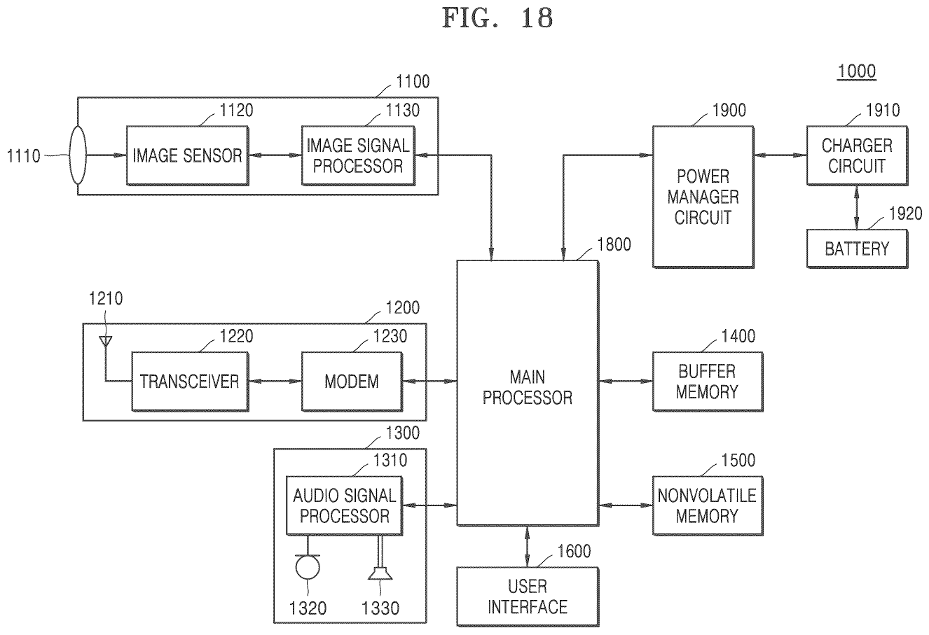

FIG. 18 is a block diagram of an electronic system 1000 according to some example embodiments.

Referring to FIG. 18, the electronic system 1000 may include various electronic circuits. For example, the electronic system 1000 may include an image processing block 1100, a communication block 1200, an audio processing block 1300, a buffer memory 1400, a nonvolatile memory 1500, a user interface 1600, a main processor 1800, a power manager circuit 1900, and a charger circuit 1910.

The electronic system 1000 may be connected to a battery 1920, and the battery 1920 may be configured to provide power used for operations of the electronic system 1000. The power provided to the electronic system 1000e may also be provided from another internal/external power in addition to the battery 1920.

The image processing block 1100 may be configured to receive light through the lens 1110. An image sensor 1120 and an image signal processor 1130 in the image processing block 1100 may be configured to generate image information regarding external objects, based on the light that is received.

The communication block 1200 may be configured to exchange signals with external devices and/or external systems through an antenna 1210. A transceiver 1220 and a modulator/demodulator (MODEM) 1230 in the communication block 1200 may be configured to process the signals exchanged with the external devices/systems, based on one or more of various wireless/wireless communication protocols.

The audio processing block 1300 may be configured to receive audio inputs through a microphone 1320 and produce audio outputs through a speaker 1330. The audio signal processor 1310 in the audio processing block 1300 may be configured to process sound information.

The buffer memory 1400 may be configured to store data used for the operations of the electronic system 1000. For example, the buffer memory 1400 may be configured to temporarily store data processed by the main processor 1800 or to be processed by the main processor 1800. For example, the buffer memory 1400 may include a volatile memory such as Static Random Access Memory (SRAM), Dynamic RAM (DRAM), Synchronous DRAM (SDRAM), and/or a nonvolatile memory such as Phase-change RAM (PRAM), Magneto-resistive RAM (MRAM), Resistive RAM (ReRAM), and Ferro-electric RAM (FRAM).

The nonvolatile memory 1500 may be configured to store data regardless of power supply. For example, the nonvolatile memory 1500 may include at least one of various types of nonvolatile memory devices such as flash memory, PRAM, MRAM, ReRAM, and FRAM. For example, the nonvolatile memory 1500 may include a detachable memory such as a Secure Digital (SD) card or a Solid State Drive (SSD), and/or an embedded memory such as an Embedded Multimedia Card (cMMC).

The user interface 1600 may be configured to intermediate communication between a user and the electronic system 1000. For example, the user interface 1600 may include an input interface configured to receive inputs from the user and an output interface configured to provide information to the user.

The main processor 1800 may be configured to control general operations of components in the electronic system 1000. The main processor 1800 may be configured to process various types of calculation to operate the electronic system 1000. For example, the main processor 1800 may be implemented as a general-purpose processor, a dedicated (or special-purpose) processor, an application processor (e.g., the application processor 400 illustrated in FIG. 1), a microprocessor, and the like, and may include one or more processor cores.

The power manager circuit 1900 may be configured to provide power to the components in the electronic system 1000 and manage the power. For example, the power manager circuit 1900 may be configured to output a system voltage based on power provided from the charger circuit 1910 and/or the battery 1920. The power manager circuit 1900 may be configured to adjust a frequency of each of the components, a voltage level of a system voltage that is provided, and the like, according to temperatures and operation modes (e.g., a performance mode, a standby mode, a slip mode) of the components.

The charger circuit 190 may be configured to charge the battery 1920 or provide power to the power manager circuit 1900 based on the power provided from the external power. Alternatively, the charger circuit 1910 may be configured to provide power to the external device through a wired or wireless power interface, based on the power provided from the battery 1920.

In some example embodiments, the charger IC 100 described above with reference to FIGS. 1 to 17 may be applied to the electronic system 1000 as the charger circuit 1910.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

It would be obvious to those skilled in the art that the structure of the inventive concepts may be variously corrected or modified without excessing the scope of the inventive concepts. Considering the above-descriptions, when corrections or modifications with respect to the inventive concepts belongs to categories of the following claims and equivalents thereof, it will be considered that the inventive concepts includes modification and corrections of the inventive concepts.

Although example embodiments have been described using specific terms, this is merely to describe the inventive concepts and not to define meanings or limit the scope of the inventive concepts written in the claims. Accordingly, those of ordinary skill in the art shall understand that various modifications and other equivalent embodiments may be made based thereon. Accordingly, the technical scope of the inventive concepts shall be defined according to the following claims.

While the inventive concepts have been particularly shown and described with reference to example embodiments thereof, it will be understood that various changes in form and details may be made therein without departing from the spirit and scope of the following claims.

What is claimed is:

1. A charger integrated circuit comprising:
a bidirectional switching converter comprising
a first switching element,
a second switching element,
a third switching element,
a fourth switching element, the first to fourth switching elements connected in series to a first input/output node,
an inductor connected between an end of the third switching element and a second input/output node, and
a capacitor connected between an end of the second switching element and another end of the third switching element;
a first bidirectional current sensor connected to an end and another end of the first switching element, the first bidirectional current sensor configured to
generate a first sensing voltage and a second sensing voltage corresponding to a first switching current flowing through the first switching element that is turned on, based on resistances set in response to turning on of the first switching element, bias currents generated internally, and a resistance of the first switching element that is turned on, and
output a first detection signal and a second detection signal indicating a result of detecting an over-current with respect to the first switching current and a result of detecting a zero-current with respect to the first switching current, based on a first reference voltage and a second reference voltage which vary according to switching modes, and the first sensing voltage and the second sensing voltage; and
a second bidirectional current sensor connected to an end and another end of the fourth switching element, the second bidirectional current sensor configured to
generate a third sensing voltage and a fourth sensing voltage corresponding to a second switching current flowing through the fourth switching element that is turned on, based on resistances set in response turning on of the fourth switching element and bias currents generated internally and a resistance of the fourth switching element that is turned on, and
output a third detection signal and a fourth detection signal indicating a result of detecting of an over-current with respect to the second switching current and a result of detecting of a zero-current with respect to the second switching current, based on the first reference voltage, the second reference voltage, the third sensing voltage, and the fourth sensing voltage.

2. The charger integrated circuit of claim 1, wherein the first bidirectional current sensor comprises:
a first sensing circuit connected to the first input/output node, connected to a second node connected to the end of the second switching element, and configured to output a first bias current, a second bias current, a first offset current, and a second offset current, based on a first switching voltage provided to the first switching element;
a first amplification circuit comprising a first input terminal connected to a seventh node from which the first bias current and the first offset current are output, a second input terminal and a third input terminal to which the second bias current is received, and a fourth input terminal connected to an eighth node from which the first bias current and the second offset current are output, the first amplification circuit being configured to output a first amplification voltage and a second amplification voltage, based on the first bias current and the second bias current;
a first sensing voltage generation circuit connected to output terminals of the first amplification circuit, the seventh node, and the eighth node, configured to output the first sensing voltage based on the first offset current and the first amplification voltage, and configured to output the second sensing voltage based on the second offset current and the second amplification voltage; and
a first detection circuit configured to output the first detection signal based on the first sensing voltage and the first reference voltage and output the second detection signal based on the second sensing voltage and the second reference voltage.

3. The charger integrated circuit of claim 2, wherein the first sensing circuit comprises:
a delay circuit configured to receive the first switching voltage, delay the first switching voltage, and output a delay enable signal in which the first switching voltage is delayed;
a level shifter configured to output a sensing control signal based on the delay enable signal;
a first sensing module connected to the first input/output node and the seventh node and configured to output the first offset current and the first bias current based on the sensing control signal;
a second sensing module connected to the second node and the second input terminal and configured to output the second bias current based on the sensing control signal;
a third sensing module connected to the first input/output node and the third input terminal and configured to output the second bias current based on the sensing control signal; and
a fourth sensing module connected to the second node and the eighth node and configured to output the first offset current and the first bias current based on the sensing control signal.

4. The charger integrated circuit of claim 3, wherein
the first sensing module comprises at least one first sensing element configured to electrically connect the first input terminal to the first input/output node as a resistor having a first resistance, in response to an active level of the sensing control signal,
the second sensing module comprises at least one second sensing element configured to electrically connect the second input terminal to the second node as a resistor having a second resistance, in response to the active level of the sensing control signal,
the third sensing module comprises at least one third sensing element configured to electrically connect the third input terminal to the first input/output node as the resistor having the second resistance, in response to the active level of the sensing control signal, and
the fourth sensing module comprises at least one fourth sensing element configured to electrically connect the fourth input terminal to the second node as the resistor having the first resistance, in response to the active level of the sensing control signal.

5. The charger integrated circuit of claim 4, wherein the second resistance is N times the first resistance, where N is greater than 1.

6. The charger integrated circuit of claim 2, wherein the first amplification is configured to
amplify a difference between the first bias current input to the first input terminal and the second bias current input to the second input terminal,
amplify a difference between the second bias current input to the third input terminal and the first bias current input to the fourth input terminal, and
output the first amplification voltage and the second amplification voltage.

7. The charger integrated circuit of claim 2, wherein the first sensing voltage generation circuit comprises
a first device connected to the seventh node, connected to a ninth node to which the first sensing voltage is applied, and configured to electrically connect the seventh node and the ninth node in response to an active level of the first amplification voltage;
a first resistor connected to the ninth node and a ground;
a second device connected to the eighth node, connected to a tenth node to which the second sensing voltage is applied, and configured to electrically connect the eighth node to the tenth node in response to an active level of the second amplification voltage; and
a second resistor connected to the tenth node and the ground.

8. The charger integrated circuit of claim 2, wherein the first detection circuit comprises:
a first detector configured to receive the first reference voltage and the first sensing voltage, determine the first detection signal based on the first reference voltage and the first sensing voltage, and output the first detection signal; and
a second detector configured to receive the second reference voltage and the second sensing voltage, determine the second detection signal based on the second reference voltage and the second sensing voltage, and output the second detection signal.

9. The charger integrated circuit of claim 2, wherein the first bidirectional current sensor further comprises
a first adjustment circuit configured to receive a first digital signal and a second digital signal, each determined according to each of a plurality of switching modes including a buck mode, a boost mode, and a buck-boost mode, and configured to selectively change a voltage level of the first reference voltage and a voltage level of the second reference voltage based on the first digital signal and the second digital signal.

10. The charger integrated circuit of claim 9, wherein the first adjustment circuit comprises:
a first current source configured to output a first current based on a first supply voltage;
a first resistor selector connected to an eleventh node, to which the first current is input, and configured to change the voltage level of the first reference voltage according to logical values of the first digital signal;
a second current source configured to output a second current based on the first supply voltage; and
a second resistor selector connected to a twelfth node, to which the second current is input, and configured to change a voltage level of the second reference voltage according to logical values of the second digital signal.

11. The charger integrated circuit of claim 1, wherein the second bidirectional current sensor comprises:
a second sensing circuit connected to a fourth node connected to the other end of the third switching element, connected to a ground, and configured to output a third bias current, a fourth bias current, a third offset current, and a fourth offset current, based on a fourth switching voltage provided to the fourth switching element;
a second amplification circuit configured to output a third amplification voltage and a fourth amplification voltage, based on the third bias current and the fourth bias current;
a second sensing voltage generation circuit configured to output the third sensing voltage based on the third offset current and the third amplification voltage, and configured to output the fourth sensing voltage based on the fourth offset current and the fourth amplification voltage; and
a second detection circuit configured to output the third detection signal based on the third sensing voltage and the first reference voltage, and configured to output the fourth detection signal based on the fourth sensing voltage and the second reference voltage.

12. A bidirectional current sensor comprising:
a sensing circuit connected to a first node and a second node, the first and second nodes connected to a switching element included in a bidirectional switching converter, the sensing circuit configured to output a plurality of bias currents and a plurality of offset currents based on a switching voltage provided to the switching element;
an amplification circuit configured to output a plurality of amplification voltages based on the plurality of bias currents;
a sensing voltage generation circuit configured to output a plurality of sensing voltages corresponding to a switching current flowing through the switching element, based on the plurality of offset currents and the plurality of amplification voltages; and
a detection circuit configured to output an over-current detection signal indicating whether an over-current for the switching current has been detected and a zero-current detection signal indicating whether a zero-current for the switching current has been detected, based on a plurality of reference voltages varying according to switching modes and the plurality of sensing voltages.

13. The bidirectional current sensor of claim 12, wherein the sensing circuit comprises:
a first sensing module connected to the first node and a seventh node and configured to output a first offset current and a first bias current from a first voltage applied to the first node, in response to an active level of a sensing control signal based on the switching voltage;
a second sensing module having a size greater than a size of the first sensing module and configured to output a second bias current from a second voltage applied to the second node, in response to the active level of the sensing control signal;
a third sensing module having a size identical to the size of the first sensing module and configured to output the second bias current from the first voltage in response to the active level of the sensing control signal; and
a fourth sensing module having a size identical to the size of the second sensing module, connected to the second node and an eighth node, and configured to output a second offset current and the first bias current from the second voltage in response to the active level of the sensing control signal.

14. The bidirectional current sensor of claim 12, wherein the amplification circuit is configured to
receive a plurality of first bias currents and a plurality of second bias currents, amplify a difference between each of the first bias currents and each of the second bias currents, and output a first amplification voltage and a second amplification voltage.

15. The bidirectional current sensor of claim 12, wherein the sensing voltage generation circuit comprises:
a first transistor comprising a first electrode connected to a seventh node of the sensing circuit, a second electrode connected to a ninth node to which a first sensing voltage is applied, and a first gate electrode to which a first amplification voltage of the plurality of amplification voltages is input;
a first resistor connected between the ninth node and a ground;
a second transistor comprising a first electrode connected to an eighth node of the sensing circuit, a second electrode connected to a tenth node to which the second sensing voltage is applied, and a second gate electrode to which a second amplification voltage of the plurality of amplification voltages is output; and
a second resistor connected between the tenth node and the ground.

16. The bidirectional current sensor of claim 15, wherein the sensing voltage generation circuit comprises:
a third transistor comprising a gate electrode connected to the ninth node;
a fourth transistor connected in series to the third transistor and comprising a gate electrode connected to the gate electrode of the third transistor and the ninth node;
a fifth transistor comprising a gate electrode connected to the tenth node; and
a sixth transistor connected in series to the fifth transistor and comprising a gate electrode connected to the gate electrode of the fifth transistor and the tenth node.

17. The bidirectional current sensor of claim 12, wherein the detection circuit comprises:
a first detector configured to receive a first reference voltage of the plurality of reference voltages and a first sensing voltage of the plurality of sensing voltages, determine a first detection signal based on the first reference voltage and the first sensing voltage, and output a signal of any one of the over-current detection signal and the zero-current detection signal as the first detection signal; and
a second detector configured to receive a second reference voltage of the plurality of reference voltages and a second sensing voltage of the plurality of sensing voltages, determine a second detection signal based on the second reference voltage and the second sensing voltage, and output a signal of another one of the over-current detection signal and the zero-current detection signal as the second detection signal.

18. The bidirectional current sensor of claim 12, further comprising
an adjustment circuit configured to receive a first digital signal and a second digital signal each determined according to each of a plurality of switching modes comprising a buck mode, a boost mode, and a buck-boost mode, and configured to selectively change a voltage level of a first reference voltage among the plurality of reference voltages and a voltage level of a second reference voltage among the plurality of reference voltages, based on the first digital signal and the second digital signal when the switching mode is transited.

19. The bidirectional current sensor of claim 18, wherein the adjustment circuit comprises:
a first current source configured to output a first current based on a first supply voltage;
a first resistor selector configured to receive the first current and change a voltage level of the first reference voltage according to logical values of the first digital signal;
a second current source configured to output a second current based on the first supply voltage; and
a second resistor selector configured to receive the second current and change a voltage level of the second reference voltage according to logical values of the second digital signal.

20. An electronic device comprising:
a battery; and
a charger integrated circuit configured to charge the battery in a buck mode, provide power to an external device based on a voltage charged in the battery in a boost mode, and perform, in a buck-boost mode, at least one of a first operation to charge the battery and a second operation to provide the power to the external device, the charger integrated circuit including
a bidirectional switching converter comprising a plurality of switching elements connected in series to a first input/output node;
a bidirectional current sensor configured to sense a first sensing voltage and a second sensing voltage corresponding to a switching current flowing through a switching element that is turned on, in response to turning on of the switching element of the plurality of switching elements, and configured to output a first detection signal and a second detection signal indicating a result of detecting an over-current with respect to the switching current and a result of detecting a zero-current with respect to the switching current, based on a first reference voltage and a second reference voltage which vary according to switching modes, and the first sensing voltage and the second sensing voltage; and
a gate driver configured to generate a plurality of switching voltages respectively provided to the plurality of switching elements, based on the first detection signal and the second detection signal.
